(19) United States
(12) Patent Application Publication
(10) Pub. No.: US 2025/0151544 A1
(43) Pub. Date: May 8, 2025

(54) DISPLAY DEVICE

(71) Applicant: Samsung Display Co., LTD., Yongin-si (KR)

(72) Inventors: Hye Seok NA, Yongin-si (KR); Min Ji KIM, Yongin-si (KR); Hyun Sung PARK, Yongin-si (KR)

(73) Assignee: Samsung Display Co., LTD., Yongin-si (KR)

(21) Appl. No.: 18/736,891

(22) Filed: Jun. 7, 2024

(30) Foreign Application Priority Data
Nov. 7, 2023 (KR) 10-2023-0152684

(51) Int. Cl. H10K 59/131; H10K 59/121; H10K 59/124

(52) U.S. Cl. CPC H10K 59/131; H10K 59/1213; H10K 59/1216; H10K 59/124

(57) ABSTRACT

A display device comprises a substrate including a display area including light emission areas, and a non-display area disposed adjacent to the display area, a circuit layer disposed on the substrate, and an element layer disposed on the circuit layer, and including light emitting elements disposed in the light emission areas. The circuit layer includes emission pixel drivers electrically connected to the light emitting elements, and gate lines electrically connected to the emission pixel drivers. The gate lines are disposed in a first gate conductive layer on a first gate insulating layer overlapping a semiconductor layer. The gate lines include first gate lines, each of which includes an extension portion extended to the non-display area and disposed in the non-display area. An extension length of the extension portion is equal to or greater than a width of the emission pixel driver in the first direction.

### CROSS-REFERENCE TO RELATED APPLICATION(S)

This application claims priority to and benefits of Korean Patent Application No. 10-2023-0152684 under 35 U.S.C. 119, filed on Nov. 7, 2023 in the Korean Intellectual Property Office, the entire contents of which are herein incorporated by reference.

### BACKGROUND

### 1. Technical Field

The disclosure relates to a display device.

### 2. Description of the Related Art

With the advancement of the information age, the demand for display devices for displaying images has increased with various forms. For example, display devices have been applied to various electronic devices such as smart phones, digital cameras, laptop computers, navigators, and smart televisions.

A display device may be a flat panel display device such as a liquid crystal display device, a field emission display device, or a light emitting display device. The light emitting display device may include an organic light emitting display device including an organic light emitting element, an inorganic light emitting display device including an inorganic light emitting element such as an inorganic semiconductor, or a micro light emitting display device including a micro light emitting element.

The organic light emitting display device may display an image by using light emitting elements, each of which may include a light emitting layer of an organic light emitting material. As the organic light emitting display device implements image display by using a self-light emitting element, the organic light emitting display device may have relatively excellent performance in terms of power consumption, response speed, light emitting efficiency, luminance, and wide viewing angle as compared with other display devices.

A surface of the display device may include a display area in which an image is displayed and a non-display area near the display area. Light emission areas for emitting light with each luminance and color may be arranged in the display area.

### SUMMARY

The display device may include emission pixel drivers electrically connected to the light emitting elements, respectively.

The emission pixel drivers may include at least one thin film transistor.

The thin film transistor may include a channel portion, a first electrode portion and a second electrode portion, which are disposed in a semiconductor layer, and a gate electrode disposed in a first gate conductive layer on a first gate insulating layer covering the semiconductor layer. The gate electrode may be provided as a portion, which overlaps the channel portion, among lines for transferring a gate signal. The first electrode portion may be connected to a side of the channel portion, and the second electrode portion may be connected to the other side of the channel portion.

The first electrode portion and the second electrode portion may include a dopant having a doping concentration higher than that of the channel portion.

As described above, after a process of disposing the first gate conductive layer, a doping process for conductorizing the other portion of the semiconductor layer except for a portion overlapped with the first gate conductive layer may be performed to provide the first electrode portion and the second electrode portion.

Since the first gate conductive layer may also be exposed to the doping process, charges due to the doping process may be accumulated in the first gate conductive layer.

However, the larger the display device is, the longer the line may be arranged, whereby more charges may be accumulated in the line of the first gate conductive layer. Therefore, an electric field due to the charges concentrated on both ends of the line may be increased to affect the semiconductor layer. Characteristics of the thin film transistors adjacent to an edge of the display area may be varied, resulting in defects such as dark spots and luminance deterioration due to the deterioration in characteristic uniformity of the thin film transistors, which may reduce display quality and lifespan of the display device.

An aspect of the disclosure is to provide a display device that may improve display quality and lifespan by preventing deterioration in characteristic uniformity of thin film transistors due to charges accumulated in lines.

The aspect of the disclosure is not limited to those mentioned above and additional aspects of the disclosure, which are not mentioned herein, will be clearly understood by those skilled in the art from the following description of the disclosure.

According to an aspect of the disclosure, a display device may include a substrate including a display area including light emission areas, and a non-display area disposed adjacent to the display area, a circuit layer disposed on the substrate, and an element layer disposed on the circuit layer, and including light emitting elements disposed in the light emission areas. The circuit layer may include emission pixel drivers electrically connected to the light emitting elements and disposed parallel with each other in a first direction and a second direction, and gate lines electrically connected to the emission pixel drivers and extended in the first direction. The gate lines may be disposed in a first gate conductive layer on a first gate insulating layer overlapping a semiconductor layer disposed on the substrate. The gate lines may include first gate lines, each of which includes an extension portion extended to the non-display area and disposed in the non-display area. An extension length of the extension portion may be equal to or greater than a width of the emission pixel driver in the first direction.

The extension length of the extension portion may be twice or three times of the width of the emission pixel driver in the first direction.

The extension portion may include a diagonal line oblique to the first direction and the second direction or at least one curve of which extension direction is variable.

An extension length of each of the first gate lines may exceed a width of the display area in the first direction.

The gate lines may further include second gate lines, each of which includes first split line portions disposed parallel with each other in the first direction. Each of the plurality of first split line portions may overlap at least one emission pixel driver.

A minimum distance between the first gate line and the second gate line, which are adjacent to each other, may be greater than a minimum distance between second gate lines, which are adjacent to each other, in the second direction.

At least one of the second gate lines may further include an auxiliary extension portion. The auxiliary extension portion may be extended from a first split line portion of the at least one of the second gate lines, which is adjacent to an edge of the display area, and may be disposed in the non-display area. An extension length of the auxiliary extension portion may exceed the width of the emission pixel driver in the first direction.

The gate lines may further include a third gate line that includes second split line portions disposed at an extension length longer than that of each of the first split line portions and disposed parallel with each other in the first direction. Each of the second split line portions may overlap two or more emission pixel drivers.

A minimum distance between the first gate line and the third gate line, which are adjacent to each other, may be greater than a minimum distance between the second gate line and the third gate line, which are adjacent to each other, in the second direction.

The circuit layer may include a second gate insulating layer overlapping the first gate conductive layer, a second gate conductive layer disposed on the second gate insulating layer, an interlayer insulating layer overlapping the second gate conductive layer, a first source drain conductive layer disposed on the interlayer insulating layer, a first planarization layer overlapping the first source drain conductive layer, a second source drain conductive layer disposed on the first planarization layer, and a second planarization layer overlapping the second source drain conductive layer.

One of the emission pixel drivers may include a first transistor electrically connected between a first node and a second node, a pixel capacitor electrically connected between a first power line for transferring a first power source and a third node, a second transistor electrically connected between a data line for transferring a data signal and the first node, a third transistor electrically connected between the second node and the third node, a fourth transistor electrically connected between the third node and a gate initialization voltage line for transferring a gate initialization voltage, a fifth transistor electrically connected between the first power line and the first node, a sixth transistor electrically connected between the second node and a fourth node, and a seventh transistor electrically connected between an anode initialization voltage line for transferring an anode initialization voltage and the fourth node. The first node may be electrically connected to a first electrode of the first transistor. The second node may be electrically connected to a second electrode of the first transistor. The third node may be electrically connected to a gate electrode of the first transistor. The fourth node may be electrically connected to one of the light emitting elements. The second transistor and the third transistor may be turned on by a scan write signal transferred through a scan write line. The fourth transistor may be turned on by a scan initialization signal transferred through a scan initialization line. The fifth transistor and the sixth transistor may be turned on by an emission control signal transferred through an emission control line. The seventh transistor may be turned on by a bias control signal transferred through a bias control line. The gate lines may include the scan write line, the scan initialization line, the emission control line and the bias control line.

According to an aspect of the disclosure, a display device may include a substrate including a display area including light emission areas, and a non-display area disposed adjacent to the display area, a circuit layer disposed on the substrate, and an element layer disposed on the circuit layer, and including light emitting elements disposed in the light emission areas. The circuit layer may include emission pixel drivers electrically connected to the light emitting elements and disposed parallel with each other in a first direction and a second direction, gate lines electrically connected to the emission pixel drivers and extended in the first direction, and a gate driving circuit disposed in a partial area of the non-display area between the display area and an edge of the substrate in the first direction, spaced apart from the display area and electrically connected to at least a portion of the gate lines. The gate lines may be disposed in a first gate conductive layer on a first gate insulating layer overlapping a semiconductor layer disposed on the substrate. The gate lines may include first gate lines, each of which includes an extension portion extended to the non-display area and disposed in the non-display area. An extension length of the extension portion may be equal to or greater than a width of the emission pixel driver in the first direction.

The circuit layer may further include gate connection lines electrically connected between at least a portion of the gate lines and the gate driving circuit.

The extension portion may include a diagonal line oblique to the first direction and the second direction or at least one curve of which extension direction is variable.

An extension length of each of the first gate lines may exceed a width of the display area in the first direction.

The gate lines may further include second gate lines, each of which includes a plurality of first split line portions disposed parallel with each other in the first direction. Each of the first split line portions may overlap at least one emission pixel driver. A minimum distance between the first gate line and the second gate line, which are adjacent to each other, may be greater than a minimum distance between first gate lines, which are adjacent to each other, or a minimum distance between second gate lines, which are adjacent to each other, in the second direction.

At least one of the second gate lines may further include an auxiliary extension portion. The auxiliary extension portion may be extended from a first split line portion of the at least one of the second gate lines, which is adjacent to an edge of the display area, and may be disposed in the non-display area. An extension length of the auxiliary extension portion may exceed the width of the emission pixel driver in the first direction.

The gate lines may further include a third gate line that includes a plurality of second split line portions disposed at an extension length longer than that of each of the first split line portions and disposed parallel with each other in the first direction. Each of the plurality of second split line portions may overlap two or more emission pixel drivers. A minimum distance between the first gate line and the third gate line, which are adjacent to each other, may be greater than a minimum distance between the second gate line and the third gate line, which are adjacent to each other, in the second direction.

The circuit layer may include a second gate insulating layer overlapping the first gate conductive layer, a second gate conductive layer disposed on the second gate insulating layer, an interlayer insulating layer overlapping the second gate conductive layer, a first source drain conductive layer disposed on the interlayer insulating layer, a first planarization layer overlapping the first source drain conductive layer, a second source drain conductive layer disposed on the first planarization layer, and a second planarization layer overlapping the second source drain conductive layer.

One of the emission pixel drivers may include a first transistor electrically connected between a first node and a second node, a pixel capacitor electrically connected between a first power line for transferring a first power source and a third node, a second transistor electrically connected between a data line for transferring a data signal and the first node, a third transistor electrically connected between the second node and the third node, a fourth transistor electrically connected between the third node and a gate initialization voltage line for transferring a gate initialization voltage, a fifth transistor electrically connected between the first power line and the first node, a sixth transistor electrically connected between the second node and a fourth node, and a seventh transistor electrically connected between an anode initialization voltage line for transferring an anode initialization voltage and the fourth node. The first node may be electrically connected to a first electrode of the first transistor. The second node may be electrically connected to a second electrode of the first transistor. The third node may be electrically connected to a gate electrode of the first transistor. The fourth node may be electrically connected to one of the light emitting elements. The second transistor and the third transistor may be turned on by a scan write signal transferred through a scan write line. The fourth transistor may be turned on by a scan initialization signal transferred through a scan initialization line. The fifth transistor and the sixth transistor may be turned on by an emission control signal transferred through an emission control line. The seventh transistor may be turned on by a bias control signal transmitted through a bias control line. The gate lines include the scan write line, the scan initialization line, the emission control line and the bias control line.

A display device according to an embodiment may include a substrate, a circuit layer disposed on the substrate, and an element layer disposed on the circuit layer. The substrate may include a display area in which light emission areas are disposed, and a non-display area disposed near the display area. The element layer may include light emitting elements respectively disposed in the light emission areas. The circuit layer may include emission pixel drivers electrically connected to the light emitting elements and arranged in parallel with each other in a first direction and a second direction, and gate lines electrically connected to the emission pixel drivers and extended in the first direction. The gate lines may be disposed in a first gate conductive layer on a first gate insulating layer covering a semiconductor layer disposed on the substrate.

According to an embodiment, the gate lines may include first gate lines, each of which includes an extension portion extended to the non-display area and disposed in the non-display area. An extension length of the extension portion may be equal to or greater than a width of the emission pixel driver in the first direction.

Since both ends of the first gate lines are not adjacent to the display area, defects, in which the semiconductor layer is damaged due to charges accumulated on both ends of the first gate lines, may be reduced.

As a result, since the deterioration in characteristic uniformity of the thin film transistor due to the charges accumulated on both ends of the first gate lines may be avoided, display quality and lifespan of the display device may be improved.

The effects according to an embodiment of the disclosure are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic cross-sectional view illustrating A-A′ of FIG. 1;

FIG. 3 is a schematic view illustrating a portion B of FIG. 1;

FIG. 4 is a schematic diagram of an equivalent circuit illustrating an emission pixel driver of FIG. 3;

FIG. 5 is a schematic cross-sectional view illustrating first and sixth transistors and a light emitting element of FIG. 4;

FIG. 6 is a schematic view illustrating gate lines of a portion C of FIG. 1 according to an embodiment;

FIGS. 7, 8, 9, 10, 11 and 12 are schematic views illustrating a portion D of FIG. 6 according to an embodiment;

FIG. 13 is a schematic view illustrating gate lines of a portion C of FIG. 1 according to an embodiment;

FIGS. 14 and 15 are enlarged schematic plan views illustrating a portion E of FIG. 13 according to an embodiment;

FIG. 16 is a schematic view illustrating gate lines of a portion C of FIG. 1 according to an embodiment;

FIG. 17 is an enlarged schematic plan view illustrating a portion E of FIG. 16;

FIG. 18 is a schematic plan view illustrating a semiconductor layer and a first gate conductive layer of a portion E of FIG. 16 according to an embodiment;

FIG. 19 is a schematic plan view illustrating a semiconductor layer and a first gate conductive layer of an emission pixel driver of FIG. 18;

FIG. 20 is a schematic view illustrating gate lines of a portion C of FIG. 1 according to an embodiment;

FIG. 21 is an enlarged schematic plan view illustrating a portion E of FIG. 20;

FIG. 22 is a schematic plan view illustrating a semiconductor layer and a first gate conductive layer of a portion E of FIG. 20 according to an embodiment;

FIG. 23 is a schematic view illustrating gate lines of a portion C of FIG. 1 according to an embodiment;

FIG. 24 is an enlarged schematic plan view illustrating a portion E of FIG. 23;

FIG. 25 is a schematic plan view illustrating a semiconductor layer and a first gate conductive layer of a portion E of FIG. 23 according to an embodiment;

FIG. 26 is a schematic view illustrating gate lines of a portion C of FIG. 1 according to an embodiment; and

FIG. 27 is an enlarged schematic plan view illustrating a portion E of FIG. 26.

### DETAILED DESCRIPTION OF THE EMBODIMENTS

Advantages and features of the disclosure and methods of accomplishing the same may be understood more readily by reference to the following detailed description of example embodiments and the accompanying drawings. The disclosure may, however, be embodied in many different forms and should not be construed as being limited to the embodiments set forth herein. Rather, these embodiments are provided so that this disclosure will be thorough and complete and will fully convey the concept of the disclosure to those skilled in the art.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that when an element or layer is referred to as being “on” another element or layer, the element or layer can be directly on another element or layer or intervening elements or layers. Like reference numerals refer to like elements throughout the specification. Shapes, sizes, ratios, angles, numbers, etc. disclosed in the drawings for describing embodiments are merely an example, and the disclosure is not limited to the illustrated details.

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

Features of various embodiments of the disclosure may be partially or entirely coupled to or combined with each other, and may be inter-operated and driven in technically various ways. Embodiments may be implemented independently from each other, or may be implemented together in a co-dependent relationship.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

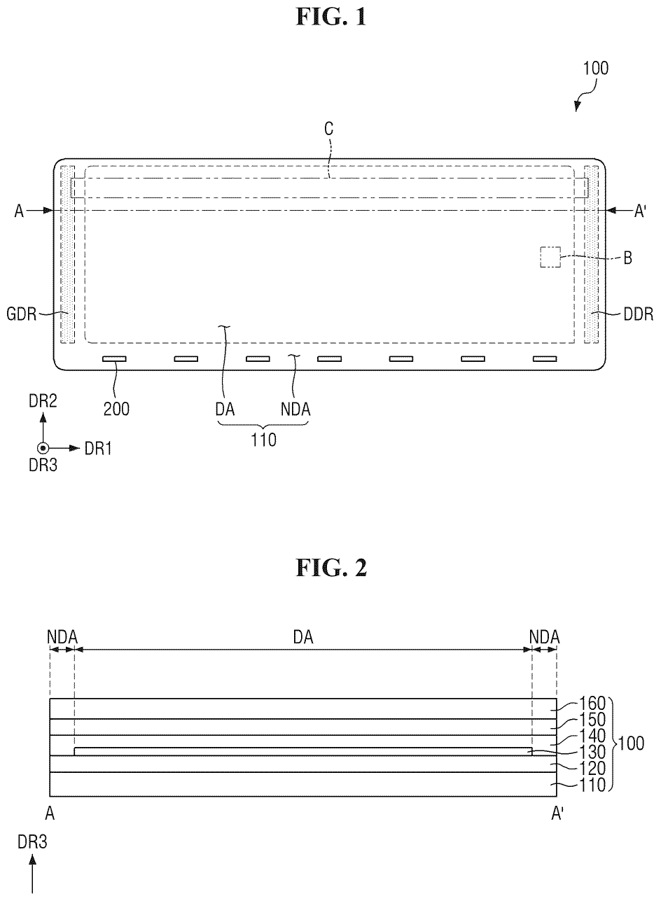

FIG. 1 is a schematic plan view illustrating a display device according to an embodiment.

The display device is a device that displays a moving image or a still image, and may be used as a display screen of various products such as a television, a laptop computer, a monitor, an advertising board and a device for Internet of things (IoT) as well as portable electronic devices such as a mobile phone, a smart phone, a tablet personal computer (PC), a smart watch, a watch phone, a mobile communication terminal, an electronic diary, an electronic book, a portable multimedia player (PMP), a navigator and an ultra mobile PC (UMPC).

The display device 100 may be a light emitting display device such as an organic light emitting display device using an organic light emitting diode, a quantum dot light emitting display device including a quantum dot light emitting layer, an inorganic light emitting display device including an inorganic semiconductor and a micro light emitting display device using a micro or nano light emitting diode (micro LED or nano LED). The following description will be based on that the display device 100 is an organic light emitting display device, but the disclosure is not limited thereto. The disclosure may be applied to a display device that includes an organic insulating material, an organic light emitting material and a metal material.

The display device 100 may be formed to be flat, but is not limited thereto. For example, the display device 100 may include a curved portion formed at left and right ends, having a constant curvature or a variable curvature. In addition, the display device 100 may be flexibly formed to be curved, bent, folded or rolled.

Referring to FIG. 1, the display device 100 according to an embodiment may include a substrate 110.

A surface of the substrate 110 may correspond to a display surface from which light for displaying an image is emitted. Most of areas of the display surface, which may be disposed at the center, may be a display area DA.

For example, a surface of the substrate 110 may include a central display area DA and a non-display area NDA disposed near (adjacent to) the display area DA.

A surface of the substrate 110 may be provided in a rectangular plane.

The display area DA may have a shape similar to that of the substrate 110.

For example, an edge of the display area DA may include four sides.

A corner of the edge of the display area DA, in which sides face each other, may be formed at a right angle, or may be rounded to have a predetermined or selected curvature. The shape of the display area DA is not limited to a rectangular shape having four sides, and may be formed in a polygonal shape other than the rectangular shape, a circular shape or an oval shape.

The non-display area NDA may be disposed between the periphery of the display area DA and the edge of the substrate 110.

A portion of the non-display area NDA may be modified in a bending shape, so that another portion of the non-display area NDA between the bent portion and the edge of the substrate 110 may be disposed on a rear surface of the substrate 110.

The display device 100 according to an embodiment may further include a gate driving circuit GDR and a display driving circuit DDR, which are disposed in a partial area of the non-display area NDA of the substrate 110.

According to an embodiment, the gate driving circuit GDR may be adjacent to two sides, which face each other in a first direction DR1, among the edges of the display area DA.

The display driving circuit DDR may be provided as an integrated circuit (IC), and may be packaged on a portion of the non-display area NDA of the substrate 110 in a Chip On Glass (COG) mode, a Chip On Plastic (COP) mode or an ultrasonic bonding method.

FIG. 2 is a schematic cross-sectional view illustrating A-A′ of FIG. 1.

Referring to FIG. 2, the display device 100 according to an embodiment includes a substrate 110, a circuit layer 120 disposed on the substrate 110, and an element layer 130 disposed on the circuit layer 120.

The display device 100 may further include a sealing layer 140 covering the element layer 130 and a touch sensor layer 150 disposed on the sealing layer 140.

The display device 100 may further include a polarizing layer 160 disposed on the touch sensor layer 150 to reduce reflection of external light.

The substrate 110 may be made of an insulating material such as a polymer resin. For example, the substrate 110 may be made of polyimide. The substrate 110 may be a flexible substrate capable of being subjected to bending, folding, rolling and the like.

The substrate 110 may be made of an insulating material such as glass.

The substrate 110 may include a display area DA and a non-display area NDA.

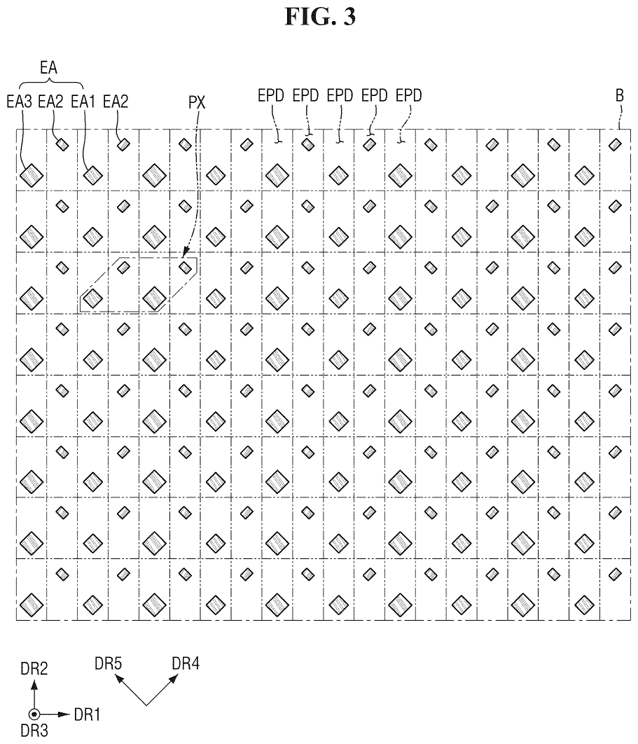

FIG. 3 is a schematic view illustrating a portion B of FIG. 1.

Referring to FIG. 3, the display area DA of the substrate 110 according to an embodiment may include light emission areas EA.

The display area DA may further include a non-light emission area disposed between the light emission areas EA.

The light emission areas EA may have a rhombus planar shape or a rectangular planar shape, but this is only an example. The planar shape of the light emission areas EA according to an embodiment is not limited to the shown example of FIG. 3. For example, the light emission areas EA may have a polygonal shape such as a rectangular shape, a pentagonal shape and a hexagonal shape, or may have a circular or oval planar shape including a curved edge.

The light emission areas EA may include first light emission areas EA1 for emitting light of a first color by a predetermined or selected wavelength band, second light emission areas EA2 for emitting light of a second color by a wavelength band lower than that of the first color, and third light emission areas EA3 for emitting light of a third color by a wavelength band lower than that of the second color.

For example, the first color may be red by a wavelength band of 600 nm to 750 nm, approximately. The second color may be green by a wavelength band of 480 nm to 560 nm, approximately. The third color may be blue by a wavelength band of 370 nm to 460 nm, approximately.

The first light emission areas EA1 and the third light emission areas EA3 may be alternately disposed in at least one of the first direction DR1 or the second direction DR2.

The second light emission areas EA2 may be arranged in parallel with each other in at least one of the first direction DR1 or the second direction DR2.

The second light emission areas EA2 may be adjacent to the first light emission areas EA1 and the third light emission areas EA3 in diagonal directions DR4 and DR5 crossing (intersecting) the first direction DR1 and the second direction DR2.

Pixels PX for displaying each luminance and color may be provided by the first light emission area EA1, the second light emission area EA2 and the third light emission area EA3, which are adjacent to one another, among the light emission areas EA.

In other words, the pixels PX may be basic units for displaying various colors including white color at predetermined or selected luminance.

Each of the pixels PX may include at least one first light emission area EA1, at least one second light emission area EA2 and at least one third light emission area EA3, which are adjacent to one another. Therefore, each pixel PX may display various colors through mixture of light emitted from the first light emission area EA1, the second light emission area EA2 and the third light emission area EA3, which are adjacent to one another.

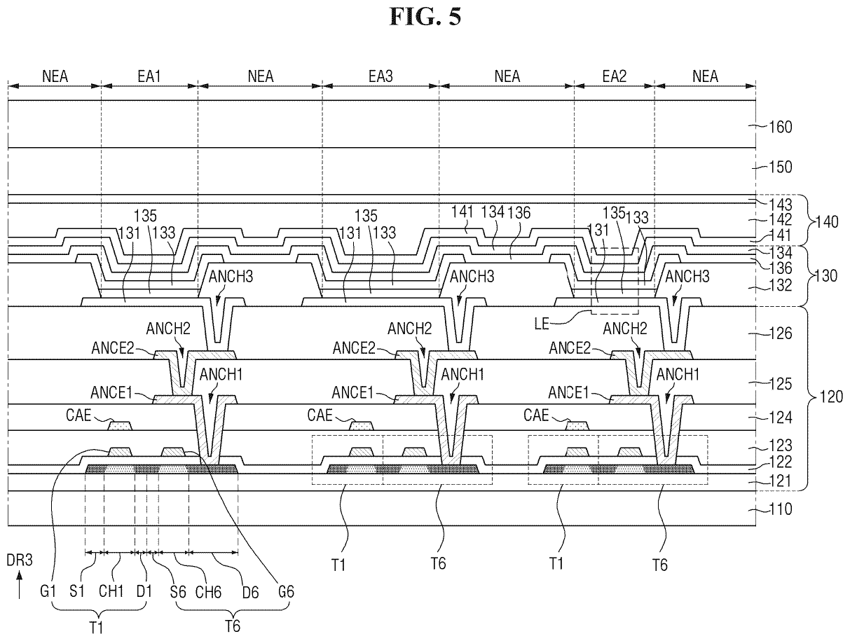

The element layer (130 of FIG. 3) of the display device 100 according to an embodiment may include light emitting elements (LE of FIG. 5) respectively disposed in the light emission areas EA.

According to an embodiment, the circuit layer 120 may include emission pixel drivers EPD electrically connected to the light emitting elements LE of the element layer 130, respectively.

The emission pixel drivers EPD may be arranged in parallel with each other in the first direction DR1 and the second direction DR2.

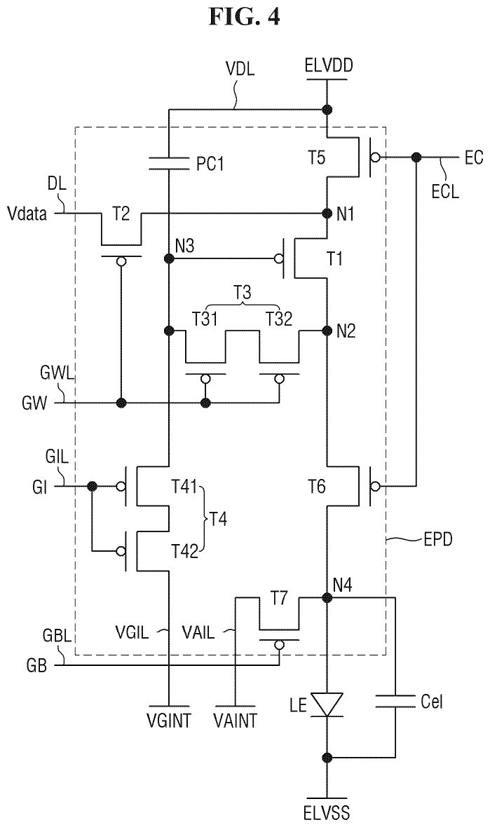

FIG. 4 is a schematic diagram of an equivalent circuit illustrating the emission pixel driver of FIG. 3.

Referring to FIG. 4, in an embodiment, one of the light emitting elements LE of the element layer 130 may be electrically connected between one of the emission pixel drivers EPD of the circuit layer 120 and a second power source ELVSS.

For example, an anode electrode of the light emitting element LE may be electrically connected to the emission pixel driver EPD, and the second power source ELVSS having a voltage level lower than that of the first power source ELVDD may be applied to a cathode electrode of the light emitting element LE.

A capacitor Cel connected to the light emitting element LE (e.g., by a fourth node N4) in parallel may represent parasitic capacitance between an anode electrode 131 and a cathode electrode 134.

The circuit layer 120 may include a scan write line GWL for transferring a scan write signal GW, a scan initialization line GIL for transferring a scan initialization signal GI, an emission control line ECL for transferring an emission control signal EC, and a bias control line GBL for transferring a bias control signal GB.

The circuit layer 120 may further include a first power line VDL for transferring a first power source ELVDD, a gate initialization voltage line VGIL for transferring a gate initialization voltage VGINT, and an anode initialization voltage line VAIL for transferring an anode initialization voltage VAINT.

One emission pixel driver EPD of the circuit layer 120 may include a first transistor T1 configured to generate a driving current for driving of the light emitting element LE, two or more transistors T2 to T7 electrically connected to the first transistor T1, and at least one pixel capacitor PC1.

The first transistor T1 may be electrically connected between a first node N1 and a second node N2. The first node N1 may be electrically connected to a first electrode of the first transistor T1, and the second node N2 may be electrically connected to a second electrode of the first transistor T1.

In other words, the first transistor T1 is connected in series with the light emitting element LE between the first power source ELVDD and the second power source ELVSS.

For example, the first electrode (for example, a source electrode) of the first transistor T1 may be electrically connected to the first power line VDL through the fifth transistor T5. The second electrode (for example, a drain electrode) of the first transistor T1 may be electrically connected to the anode electrode of the light emitting element LE through the sixth transistor T6.

A gate electrode of the first transistor T1 may be electrically connected to the first power line VDL through the pixel capacitor PC1. For example, the pixel capacitor PC1 may be electrically connected between a third node N3 and the first power line VDL. The third node N3 may be electrically connected to the gate electrode of the first transistor T1.

Therefore, a potential of the gate electrode of the first transistor T1 may be maintained as the first power source ELVDD by the first power line VDL.

The first electrode of the first transistor T1 may be electrically connected to a data line DL through the second transistor T2.

Therefore, in case that a data signal Vdata of the data line DL is transferred to the first electrode of the first transistor T1 through the second transistor T2 that is turned on, a voltage difference between the gate electrode of the first transistor T1 and the first electrode of the first transistor T1 may correspond to the first power source ELVDD and the data signal Vdata.

At this time, in case that the voltage difference between the gate electrode of the first transistor T1 and the first electrode of the first transistor T1, for example, a gate-source voltage difference reaches a threshold voltage or more, the first transistor T1 is turned on, so that a drain-source current of the first transistor T1 corresponding to the data signal Vdata may be generated.

Subsequently, in case that the fifth transistor T5 and the sixth transistor T6 are turned on, the first transistor T1 may be connected in series with the light emitting element LE between the first power line VDL and a second power line. Therefore, the drain-source current of the first transistor T1, which corresponds to the data signal Vdata, may be supplied as a driving current of the light emitting element LE.

Therefore, the light emitting element LE may emit light of luminance corresponding to the data signal Vdata.

The second transistor T2 may be electrically connected between the first node N1 and the data line DL.

The second transistor T2 may be turned on by the scan write signal GW of the scan write line GWL.

The third transistor T3 may be electrically connected between the third node N3 and the second electrode of the first transistor T1.

The third transistor T3 may be turned on by the scan write signal GW of the scan write line GWL.

The third transistor T3 may include sub-transistors connected in series. For example, the third transistor T3 may include a first sub-transistor T31 and a second sub-transistor T32. The potential of the gate electrode of the first transistor T1 may be prevented from being changed due to a leakage current through the third transistor T3 that is in a turn-off state.

The fourth transistor T4 may be electrically connected between the third node N3 and the gate initialization voltage line VGIL.

The fourth transistor T4 may be turned on by the scan initialization signal GI of the scan initialization line GIL.

The fourth transistor T4 may include sub-transistors connected in series. For example, the fourth transistor T4 may include a third sub-transistor T41 and a fourth sub-transistor T42. The potential of the gate electrode of the first transistor T1 may be prevented from being changed due to a leakage current through the fourth transistor T4 that is in a turn-off state.

The fifth transistor T5 may be electrically connected between the first node N1 and the first power line VDL.

The sixth transistor T6 may be electrically connected between the second node N2 and the anode electrode of the light emitting element LE.

The fifth transistor T5 and the sixth transistor T6 may be turned on by the emission control signal EC of the emission control line ECL.

The seventh transistor T7 may be electrically connected between the anode electrode of the light emitting element LE and the anode initialization voltage line VAIL.

The seventh transistor T7 may be turned on by the bias control signal GB of the bias control line GBL.

As shown in FIG. 4, the first to seventh transistors T1 to T7 may be provided as P-type MOSFET, but this is only an example, and some of the first to seventh transistors T1 to T7 may be provided as N-type MOSFET. For example, the third transistor T3 and the fourth transistor T4 of the first to seventh transistors T1 to T7 may be provided as N-type MOSFET.

FIG. 5 is a schematic cross-sectional view illustrating the first and sixth transistors and the light emitting element of FIG. 4.

Referring to FIG. 5, the display device 100 according to an embodiment may include a substrate 110, a circuit layer 120 on the substrate 110, and an element layer 130 on the circuit layer 120.

The display device 100 may further include a sealing layer 140 on the element layer 130, a touch sensor layer 150 on the sealing layer 140, and a polarizing layer 160 disposed on the touch sensor layer 150.

According to an embodiment, the circuit layer 120 may include first semiconductor layers CH1, S1, D1, CH6, S6 and D6 disposed on the substrate 110, a first gate insulating layer 122 covering the semiconductor layer, and first gate conductive layers G1 and G6 disposed on the first gate insulating layer 122.

According to an embodiment, the circuit layer 120 may further include a second gate insulating layer 123 covering the first gate conductive layer, a second gate conductive layer CAE disposed on the second gate insulating layer 123, an interlayer insulating layer 124 covering the second gate conductive layer, a first source drain conductive layer ANCE1 disposed on the interlayer insulating layer 124, a first planarization layer 125 covering the first source drain conductive layer, a second source drain conductive layer ANCE2 disposed on the first planarization layer 125, and a second planarization layer 126 covering the second source drain conductive layer.

The circuit layer 120 may further include a buffer layer 121 covering the substrate 110. The semiconductor layer may be disposed on the buffer layer 121.

The semiconductor layer may include a channel portion, a source portion and a drain portion of each of the transistors provided as P-type MOSFETs.

The first gate conductive layer on the first gate insulation layer 122 covering the semiconductor layer may include a gate electrode of each of the transistors provided as P-type MOSFETs.

The first gate conductive layer may further include gate lines electrically connected to the gate electrode of the transistors provided as MOSFETs.

For example, the first transistor T1 may include a channel portion CH1, a source portion S1 and a drain portion D1, which are disposed in the semiconductor layer on the substrate 110, and a gate electrode G1 disposed in the first gate conductive layer on the first gate insulating layer 122 covering the semiconductor layer. The source portion S1 and the drain portion D1 may be connected to both ends of the channel portion CH1. The source portion S1 and the drain portion D1 may be doped at a concentration higher than that of the channel portion CH1. The gate electrode G1 may overlap the channel portion CH1.

Likewise, the sixth transistor T6 may include a channel portion CH6, a source portion S6 and a drain portion D6, which are disposed in the semiconductor layer on the substrate 110, and a gate electrode G6 disposed in the first gate conductive layer on the first gate insulating layer 122 covering the semiconductor layer.

According to an embodiment, the second to fifth transistors T2 to T5 and the seventh transistor T7 are P-type MOSFETs like the first transistor T1 and the sixth transistor T6, and thus their redundant description will be omitted.

The second gate conductive layer on the second gate insulating layer 123 covering the first gate conductive layers G1 and G6 may include a capacitor electrode CAE.

The capacitor electrode CAE may overlap the gate electrode G1 of the first transistor T1.

Thus, the pixel capacitor PC1 may be provided as an overlap area between the gate electrode G1 of the first transistor T1 and the capacitor electrode CAE.

The first source drain conductive layer on the interlayer insulating layer 124 covering the second gate conductive layer may include a first anode connection electrode ANCE1.

The first anode connection electrode ANCE1 may be electrically connected to the drain portion D6 of the sixth transistor T6 through a first anode contact hole ANCH1 passing through the interlayer insulating layer 124, the second gate insulating layer 123 and the first gate insulating layer 122.

The second source drain conductive layer on the first planarization layer 125 covering the first source drain conductive layer may include a second anode connection electrode ANCE2.

The second anode connection electrode ANCE2 may be electrically connected to the first anode connection electrode ANCE1 through a second anode contact hole ANCH2 passing through the first planarization layer 125.

The anode electrode 131 of the element layer 130 may be disposed on the second planarization layer 126, and may be electrically connected to the second anode connection electrode ANCE2 through a third anode contact hole ANCH3 passing through the second planarization layer 126.

Thus, the anode electrode 131 may be electrically connected to the drain portion D6 of the sixth transistor T6 through the first anode connection electrode ANCE1 and the second anode connection electrode ANCE2.

The element layer 130 may be disposed on the second planarization layer 126, and may include light emitting elements LE corresponding to the light emission areas EA, respectively.

Each of the light emitting elements LE may include an anode electrode 131 and a cathode electrode 134, which face each other, and a light emitting layer 133 disposed between the anode electrode 131 and the cathode electrode 134.

In another embodiment, each of the light emitting elements LE may further include a first common layer 135 disposed between the anode electrode 131 and the light emitting layer 133, and a second common layer 136 disposed between the light emitting layer 133 and the cathode electrode 134.

For example, the element layer 130 may include anode electrodes 131 respectively corresponding to the light emission areas EA, a pixel defining layer 132 corresponding to the non-light emission area NEA and covering an edge of the anode electrode 131, light emitting layers 133 disposed on the anode electrodes 131, respectively, and a cathode electrode 134 disposed on the light emitting layers 133 and the pixel defining layer 132.

The anode electrode 131 may be disposed in each of the light emission areas EA and may be electrically connected to one emission pixel driver EPD of the circuit layer 120. The anode electrode 131 may be referred to as a pixel electrode.

The anode electrode 131 may be electrically connected to the second anode connection electrode ANCE2 through the third anode contact hole ANCH3 passing through the second planarization layer 126.

The light emitting layer 133 may be made of an organic light emitting material that converts electron-hole pairs into light.

The cathode electrode 134 may be disposed on the light emitting layers 133 and the pixel defining layer 132 of the light emission areas EA. The second power source ELVSS may be applied to the cathode electrode 134. The cathode electrode 134 may be referred to as a common electrode.

The sealing layer 140 may be disposed on the circuit layer 120, and may cover the element layer 130.

The sealing layer 140 may include a first sealing layer 141 disposed on the element layer 130 and made of an inorganic insulating material, a second sealing layer 142 disposed on the first sealing layer 141, overlapped with the element layer 130 and made of an organic insulating material, and a third sealing layer 143 disposed on the first sealing layer 141, covering the second sealing layer 142 and made of an inorganic insulating material.

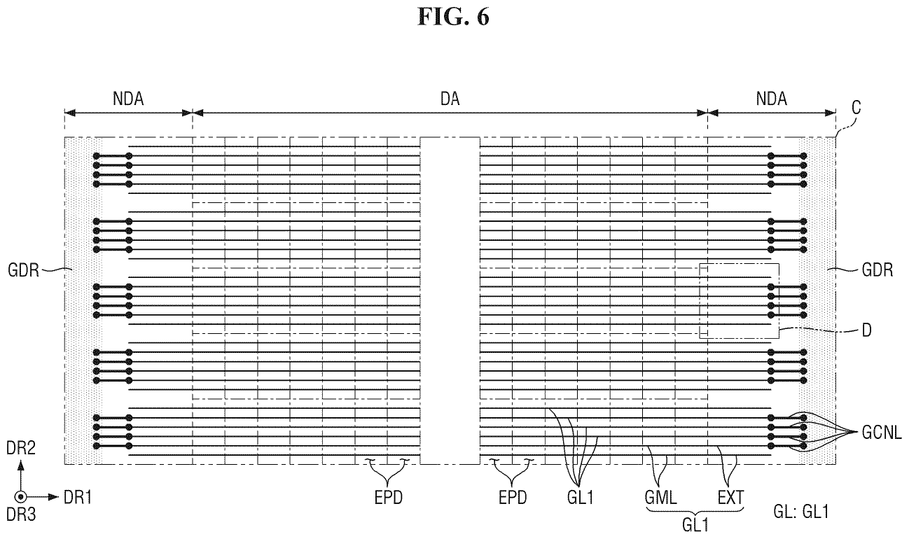

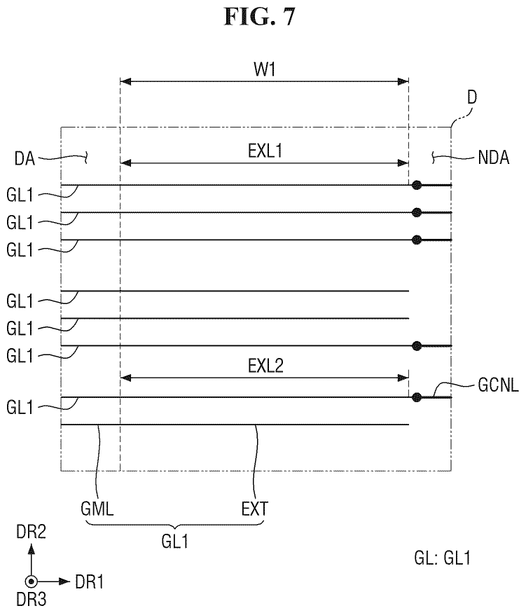

FIG. 6 is a schematic view illustrating gate lines of a portion C of FIG. 1 according to an embodiment. FIGS. 7, 8, 9, 10, 11 and 12 are schematic views illustrating a portion D of FIG. 6 according to an embodiment.

Referring to FIG. 6, the circuit layer 120 of the display device 100 according to an embodiment includes emission pixel drivers EPD arranged in parallel with each other in the first direction DR1 and the second direction DR2, and gate lines GL electrically connected to the emission pixel drivers EPD and extended in the first direction DR1.

According to an embodiment, the gate lines GL may be disposed in the first gate conductive layer on the first gate insulating layer (122 of FIG. 5) covering the semiconductor layers (CH1, S1, D1, CH6, S6 and D6) disposed on the substrate (110 of FIG. 5).

According to an embodiment, the gate driving circuit GDR may be electrically connected to at least some gate lines, which are electrically connected to the transistor of the emission pixel driver EPD, among the gate lines GL.

According to an embodiment, the circuit layer 120 may further include gate connection lines GCNL electrically connected between at least some of the gate lines GL and the gate driving circuit GDR.

The gate connection lines GCNL may be electrically connected to one end of at least some of the gate lines GL, but this is only an example.

An end of the gate connection lines GCNL may be spaced apart from an end of at least some of the gate lines GL. For example, the gate connection lines GCNL may cross at least some of the gate lines GL, respectively.

The gate lines GL may include first gate lines GL1. For example, at least a portion of the gate lines GL may be disposed as the first gate line GL1.

According to an embodiment, the entire gate lines GL may be disposed as the first gate lines GL1.

Each of the first gate lines GL1 may have a single line shape.

Therefore, as the display device 100 becomes larger, a length of the first gate lines GL1 is increased, so that the amount of charges accumulated in each of the first gate lines GL1 may be increased during the doping process. For this reason, the electric field due to the charges concentrated on both ends of the first gate line GL1 may be generated to have a large size that can affect the semiconductor layer.

Therefore, according to an embodiment, in order to reduce an influence of the electric field due to the charges concentrated on both ends of the first gate line GL1, each of the first gate lines GL1 may include an extension portion EXT extended to the non-display area NDA and disposed in the non-display area NDA.

For example, each of the first gate lines GL1 may include a main line portion GML disposed in the display area DA, and extension portions EXT connected to both ends of the main line portion GML and disposed in the non-display area NDA.

The main line portion GML may overlap the emission pixel drivers EPD arranged in parallel with each other in the first direction DR1, and may be in contact with the edge of the display area DA. For example, an extension length of the main line portion GML may be in the same range as a width of the display area DA in the first direction DR1.

The extension portion EXT may be disposed in a portion of the non-display area NDA, which is between the display area DA and the gate driving circuit GDR.

As an example, the extension portion EXT may be extended from the edge of the display area DA to the gate connection line GCNL.

An extension length of the extension portion EXT may be equal to or greater than a width of the emission pixel driver EPD in the first direction DR1.

For example, the extension length of the extension portion EXT may be twice or three times of the width of the emission pixel driver EPD in the first direction DR1.

As an example, in case that the width of the emission pixel driver EPD in the first direction DR1 is about 50 μm or less, the extension length of the extension portion EXT may be about 100 μm or more or about 150 μm or more.

In this way, as both ends of the first gate line GL1 are sufficiently spaced apart from the semiconductor layer of the display area DA, the influence of the electric field on the semiconductor layer due to the charges concentrated on both ends of the first gate line GL1 may be reduced.

As the first gate line GL1 includes extension portions EXT connected to both ends of the main line portion GML, the extension length of each of the first gate lines GL1 may be equal to or greater than the width of the display area DA in the first direction DR1. Both ends of the first gate line GL1 may be spaced apart from the edge of the display area DA.

In this way, the influence of the electric field on the semiconductor layer of the display area DA due to the charges concentrated on both ends of the first gate line GL1 may be reduced. Therefore, characteristic uniformity of the transistors including the channel portion overlapped with the first gate lines GL1 may be prevented from being deteriorated.

As shown in the drawing of FIG. 7, according to an embodiment, the extension portion EXT of the first gate line GL1 may be extended in the first direction DR1. An extension length EXL1 of the extension portion EXT may be limited to a width or less between the edge of the display area DA and the gate driving circuit GDR.

For example, in case that the first gate line GL1 is electrically connected to the gate driving circuit GDR, the extension portion EXT of the first gate line GL1 may be extended in the first direction DR1, and may reach an end portion of the gate connection line GCNL. The extension length EXL1 of the extension portion EXT may be within a width W1 in the first direction DR1 between the edge of the display area DA and the gate connection line GCNL.

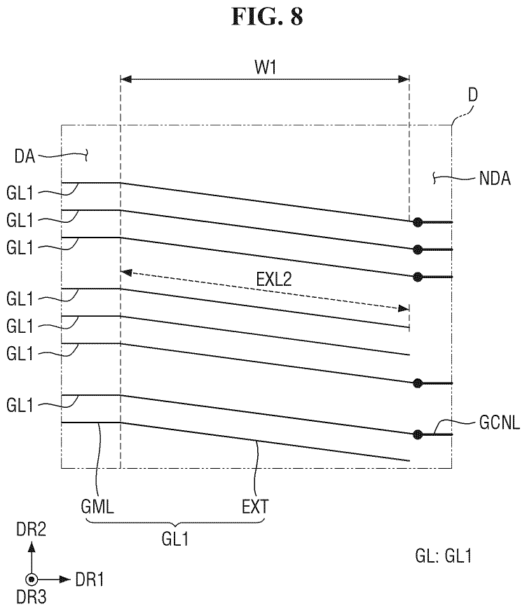

In another embodiment, as shown in FIG. 8, the extension portion EXT of the first gate line GL1 may be extended in an inclined direction oblique to the first direction DR1 and the second direction DR2.

In case that the extension portion EXT of the first gate line GL1 extended in a diagonal direction reaches the end portion of the gate connection line GCNL, an extension length EXL2 of the extension portion EXT may be greater than the width W1 in the first direction DR1 between the edge of the display area DA and the gate connection line GCNL.

In another embodiment, the extension portion EXT of the first gate line GL1 may include a diagonal line oblique to the first direction DR1 and the second direction DR2, or at least one inflection point KNP of which extension direction is variable.

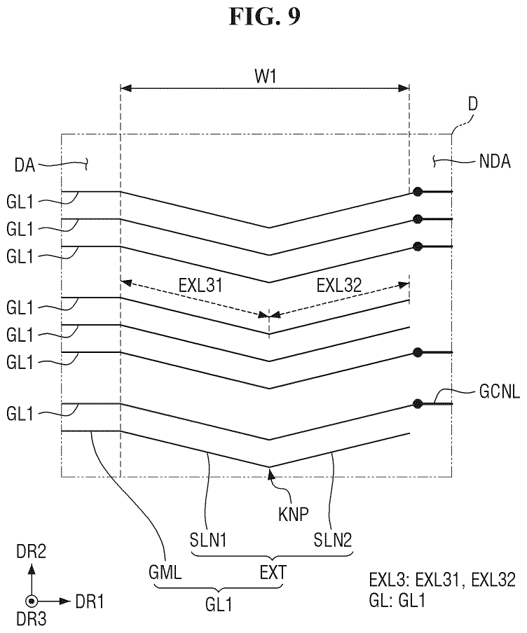

For example, as shown in FIG. 9, the extension portion EXT of the first gate line GL1 may include a first diagonal line SLN1 disposed between one end of the main line portion GML adjacent to the edge of the display area DA and the inflection point KNP, and a second diagonal line SNL2 extended from the inflection point KNP.

An extension length EXL3 of the extension portion EXT that includes the first diagonal line SLN1 and the second diagonal line SNL2 may be derived as a sum of an extension length EXL31 of the first diagonal line SLN1 and an extension length EXL32 of the second diagonal line SLN2.

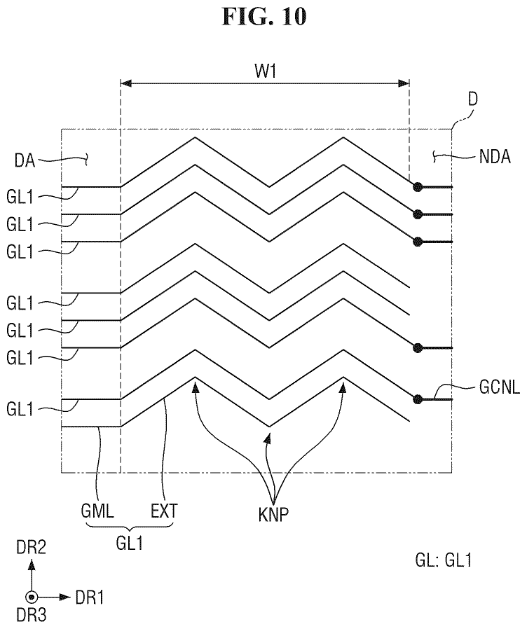

In another embodiment, as shown in FIG. 10, the extension portion EXT of the first gate line GL1 may have an uneven shape that includes two or more inflection points KNP and two or more diagonal lines.

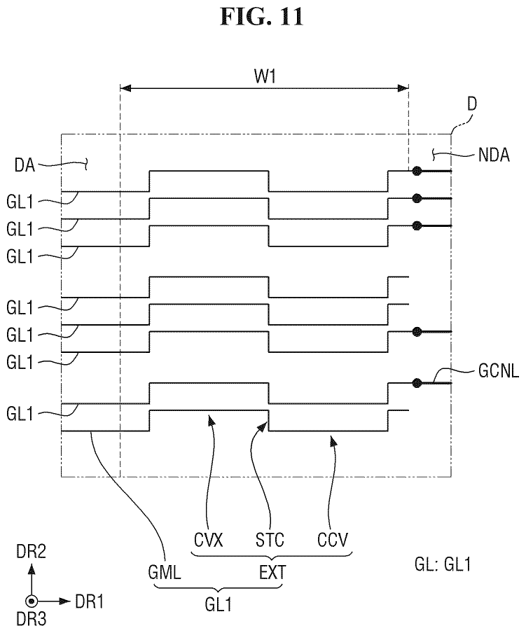

In another embodiment, as shown in FIG. 11, the extension portion EXT of the first gate line GL1 may have an uneven shape that includes a step difference connection line STC extended in the second direction DR2 between a convex portion CCV and a concave portion CVX.

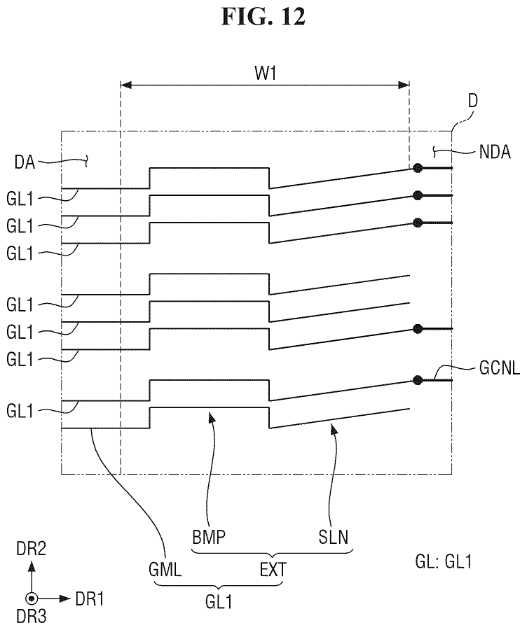

In another embodiment, as shown in FIG. 12, the extension portion EXT of the first gate line GL1 may have a shape in which a bump BMP and a diagonal line SLN are mixed.

Since a length in which both ends of the first gate line GL1 are spaced apart from the display area DA may be greater than the width W1 in the first direction DR1 between the edge of the display area DA and the gate connection line GCNL, the influence of the electric field due to the charges accumulated on both ends of the first gate line GL1 may be further reduced.

The shape of the extension portion EXT shown in FIGS. 7 to 12 are only examples, and embodiments are not limited to those shown in FIGS. 7 to 12. For example, the shape of the extension portion EXT may be modified within the range that the extension portion EXT is disposed between the edge of the display area DA and the gate driving circuit GDR and a short defect is not caused.

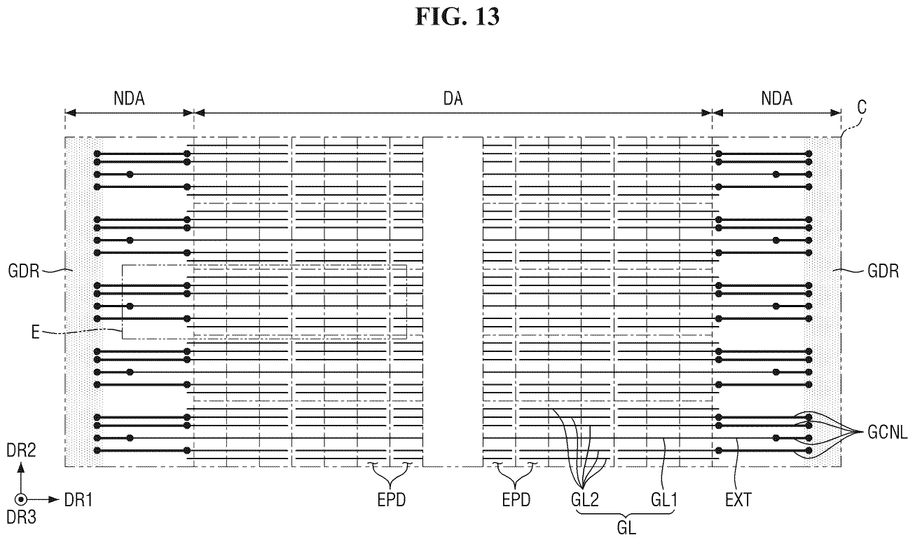

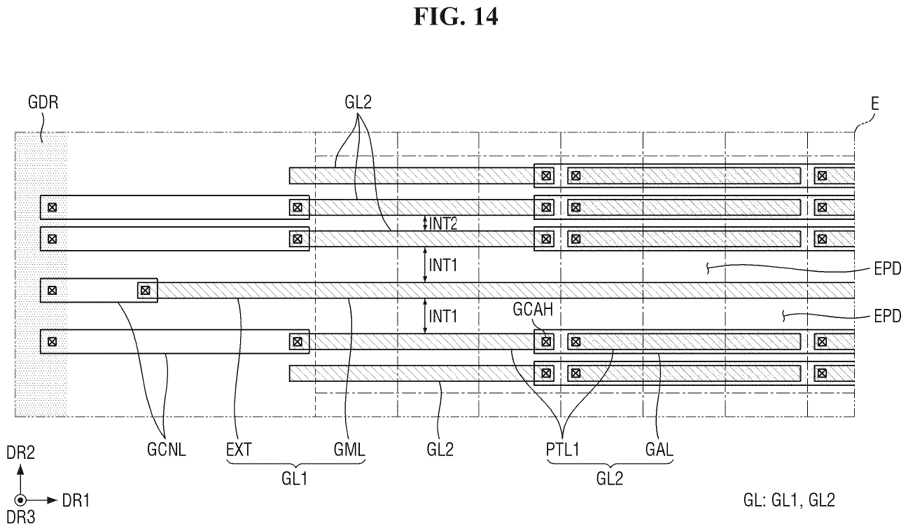

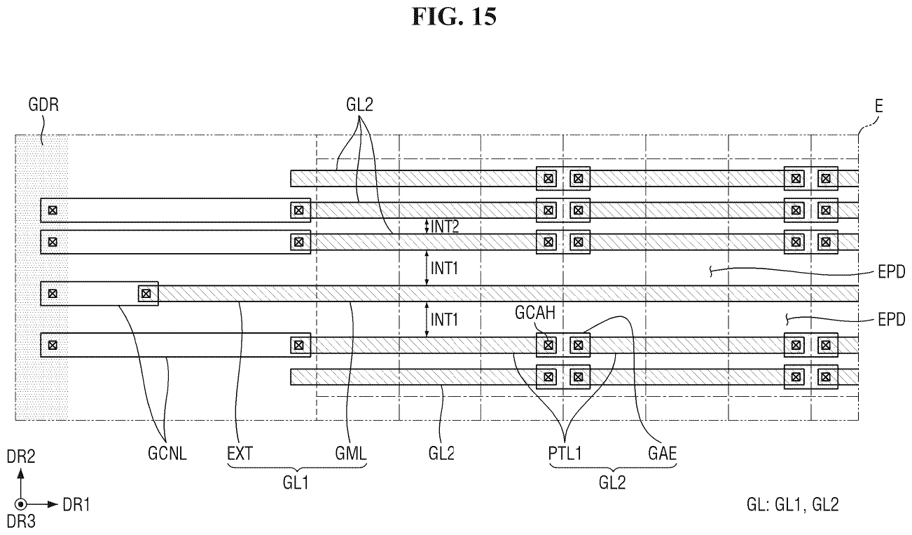

FIG. 13 is a schematic view illustrating gate lines of a portion C of FIG. 1 according to an embodiment. FIGS. 14 and 15 are enlarged schematic plan views illustrating a portion E of FIG. 13 according to an embodiment.

Referring to FIG. 13, the display device 100 according to an embodiment may be substantially the same as the embodiments shown in FIGS. 1 to 12 except that the gate lines GL may further include second gate lines GL2 as well as the first gate lines GL1. Therefore, the redundant description of FIGS. 1 to 12 will be omitted.

Each of the first gate lines GL1 may include an extension portion EXT disposed in a single line shape and extended to the non-display area NDA.

Each of the second gate lines GL2 may be disposed in the display area DA in a shape divided into two or more portions.

Referring to FIG. 14, the first gate line GL1 may include a main line portion GML of a single line disposed in the display area DA, and extension portions EXT disposed in the non-display area NDA and connected to both ends of the main line portion GML.

According to an embodiment, as shown in FIG. 14, each of the second gate lines GL2 may include multiple first split line portions PTL1 arranged in parallel with each other in the first direction DR1.

Each of the second gate lines GL2 may further include a gate auxiliary line GAL electrically connected to the first split line portions PTL1.

The first split line portions PTL1 may be disposed on the same layer as the first gate lines GL1, for example, the first gate conductive layer.

The gate auxiliary line GAL may be disposed on a conductive layer different from the first gate conductive layer, and may be electrically connected to the first split line portions PTL1 through gate connection auxiliary holes GCAH. For example, the gate auxiliary line GAL may be disposed on the second gate conductive layer. For another example, the gate auxiliary line GAL may be disposed on the conductive layer between the substrate 110 and the buffer layer 121.

Therefore, the first split line portions PTL1 may be electrically connected to each other through the gate auxiliary line GAL.

Each of the first split line portions PTL1 may overlap at least one emission pixel driver EPD.

For example, as shown in FIG. 14, each of the first split line portions PTL1 may overlap three emission pixel drivers EPD.

As described above, according to an embodiment, the second gate line GL2 may include multiple first split line portions PTL1 disposed in the first gate conductive layer, and each of the first split line portions PTL1 may be disposed to have an extension length shorter than that of the main line portion GML of the first gate line GL1.

Therefore, during the doping process, since the amount of charges accumulated in each of the first split line portions PTL1 is smaller than the amount of charges accumulated in the first gate line GL1, the electric field due to the charges concentrated on both ends of each of the first split line portions PTL1 may be of a slight size that is not affected by the semiconductor layer.

Therefore, the difference in characteristics uniformity between the transistors due to the second gate line GL2 may be avoided.

According to an embodiment, in the second direction DR2, a minimum distance INT1 between the first gate line GL1 and the second gate line GL2, which are adjacent to each other, may be greater than a minimum distance between the first gate lines GL1 adjacent to each other or a minimum distance INT2 between the second gate lines GL2 adjacent to each other.

In case that the first gate lines GL1 adjacent to each other are disposed, the minimum distance INT1 between the first gate line GL1 and the second gate line GL2, which are adjacent to each other, may be greater than a minimum distance between the first gate lines GL1, which are adjacent to each other.

As the first gate line GL1 and the second gate line GL2, which are adjacent to each other, are sufficiently spaced apart from each other, occurrence of the electric field due to the difference between the amount of charges accumulated in two of the first split line portions PTL1, which are adjacent to both ends of the first gate line GL1, among the second gate lines GL2 and the amount of charges concentrated on both ends of the first gate line GL1 may be suppressed.

Therefore, damage to the semiconductor layer due to the charges accumulated in the line may be reduced.

According to an embodiment of FIG. 14, the second gate line GL2 may include a gate auxiliary line GAL electrically connected to the first split line portions PTL1.

In another embodiment, referring to FIG. 15, the second gate line GL2 may include gate auxiliary electrodes GAE, which are electrically connected to two of the first split line portions PTL1 adjacent to each other, among the first split line portions PTL1, instead of the gate auxiliary line GAL.

The embodiment of FIG. 15 may be substantially the same as the embodiment of FIG. 14 except that the second gate line GL2 may include gate auxiliary electrodes GAE instead of the gate auxiliary line GAL. Therefore, the redundant description of FIG. 14 will be omitted.

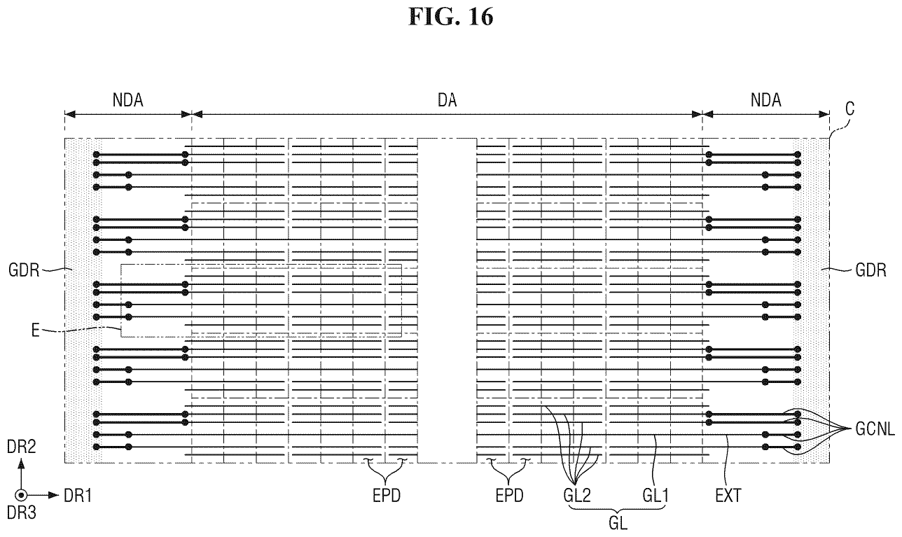

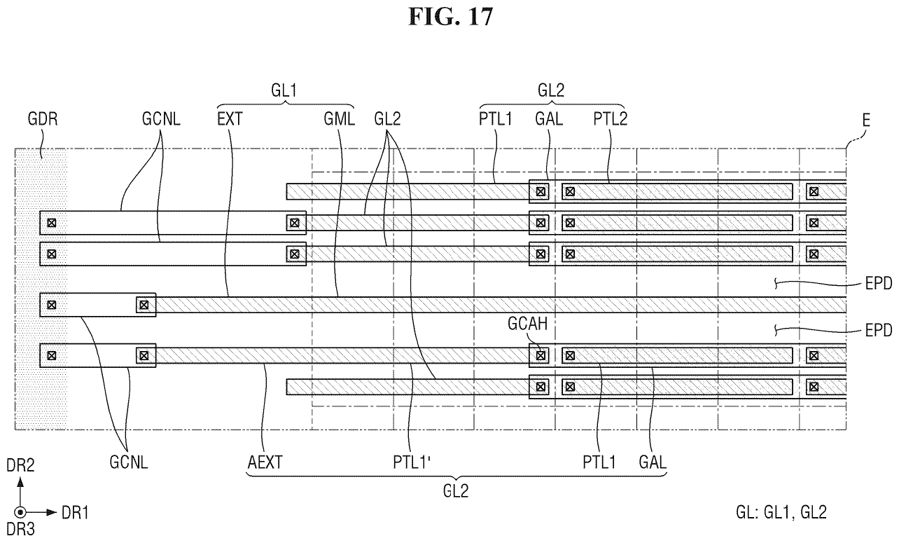

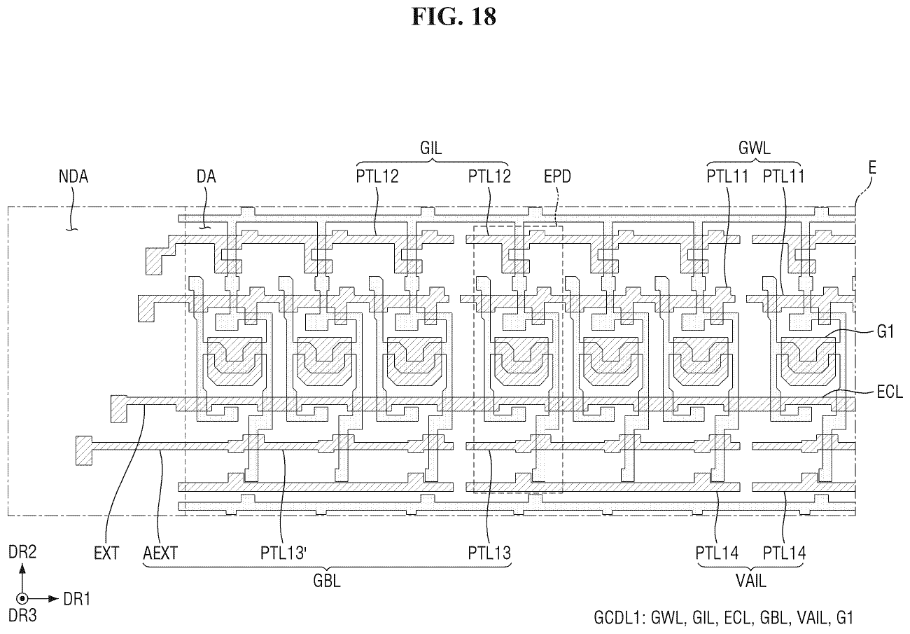

FIG. 16 is a schematic view illustrating gate lines of a portion C of FIG. 1 according to an embodiment. FIG. 17 is an enlarged schematic plan view illustrating a portion E of FIG. 16. FIG. 18 is a schematic plan view illustrating a semiconductor layer and a first gate conductive layer of a portion E of FIG. 16 according to an embodiment.

Referring to FIG. 16, the display device 100 according to an embodiment may be substantially the same as the embodiments of FIGS. 13 to 15 except that at least one of the second gate lines GL2 may further include an auxiliary extension portion AEXT. Therefore, the redundant description of FIGS. 13 to 15 will be omitted.

As shown in FIG. 17, the auxiliary extension portion AEXT may be extended from a first split line portion PTL1′ adjacent to the edge of the display area DA of at least one second gate line GL2 and disposed in the non-display area NDA.

For example, as shown in FIG. 18, the gate lines GL in the first direction DR1, which are disposed in the first gate conductive layer GCDL1, may include a scan write line GWL, a scan initialization line GIL, an emission control line ECL and a bias control line GBL.

According to an embodiment shown in FIG. 18, the gate lines GL in the first direction DR1, which are disposed in the first gate conductive layer GCDL1, may further include an anode initialization voltage line VAIL.

The emission control line ECL of the gate lines GL may be disposed as the first gate line GL1 having a single line shape including the extension portion EXT.

Each of the scan write line GWL, the scan initialization line GIL, the bias control line GBL and the anode initialization voltage line VAIL of the gate lines GL may be disposed as the second gate line GL2 having a split shape.

The bias control line GBL may include an auxiliary extension portion AEXT extended from a first split line portion PTL13′ adjacent to the edge of the display area DA.

For example, the first gate conductive layer GCDL1 may include an emission control line ECL, first split line portions PTL11 of the scan write line GWL, first split line portions PTL12 of the scan initialization line GIL, first split line portions PTL13 and PTL13′ and an auxiliary extension portion AEXT of the bias control line GBL, and first split line portions PTL14 of the anode initialization voltage line VAIL.

The first gate conductive layer GCDL1 may further include a gate electrode G1 of the first transistor T1.

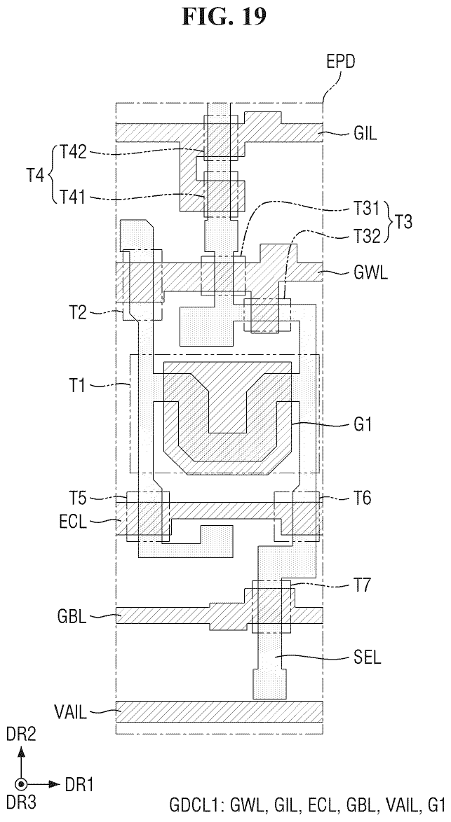

Referring to FIG. 19, the emission pixel driver EPD may include first to seventh transistors T1 to T7.

The first gate conductive layer GCDL1 may include a scan write line GWL, a scan initialization line GIL, an emission control line ECL, a bias control line GBL, an anode initialization voltage line VAIL, and a gate electrode G1 of the first transistor T1.

A semiconductor layer SEL may include a channel portion (CH1 of FIG. 5) of the first transistor T1, which overlaps the gate electrode G1 of the first transistor T1, a source portion (S1 of FIG. 5) of the first transistor T1 connected to a side of the channel portion CH1 of the first transistor T1, and a drain portion (D1 of FIG. 5) of the first transistor T1 connected to a side of the channel portion CH1 of the first transistor T1.

The third transistor T3 may include a first sub-transistor T31 and a second sub-transistor T32.

A gate electrode of the second transistor T2, a gate electrode of the first sub-transistor T31 and a gate electrode of the second sub-transistor T32 may be provided as different portions, which overlap the semiconductor layer SEL, among the scan write lines GWL.

The semiconductor layer SEL may further include a channel portion of the second transistor T2, which overlaps the gate electrode of the second transistor T2, a source portion of the second transistor T2, which is connected to a side of the channel portion of the second transistor T2, and a drain portion of the second transistor T2, which is connected to a side of a channel portion CH2 of the second transistor T2.

The semiconductor layer SEL may further include a channel portion of the first sub-transistor T31, which overlaps the gate electrode of the first sub-transistor T31, a source portion of the first sub-transistor T31, which is connected to a side of the channel portion of the first sub-transistor T31, a drain portion of the first sub-transistor T31, which is connected to a side of a channel portion CH2 of the first sub-transistor T31, a channel portion of the second sub-transistor T32, which overlaps the gate electrode of the second sub-transistor T32, a source portion of the second sub-transistor T32, which is connected to a side of the channel portion of the second sub-transistor T32, and a drain portion of the second sub-transistor T32, which is connected to a side of a channel portion CH2 of the second sub-transistor T32.

The fourth transistor T4 may include a third sub-transistor T41 and a fourth sub-transistor T42.

A gate electrode of the third sub-transistor T41 and a gate electrode of the fourth sub-transistor T42 may be provided as different portions, which overlap the semiconductor layer SEL, among the scan initialization line GIL.

The semiconductor layer SEL may further include a channel portion of the third sub-transistor T41, which overlaps the gate electrode of the third sub-transistor T41, a source portion of the third sub-transistor T41, which is connected to a side of the channel portion of the third sub-transistor T41, a drain portion of the third sub-transistor T41, which is connected to a side of a channel portion CH2 of the third sub-transistor T41, a channel portion of the fourth sub-transistor T42, which overlaps the gate electrode of the fourth sub-transistor T42, a source portion of the fourth sub-transistor T42, which is connected to a side of the channel portion of the fourth sub-transistor T42, and a drain portion of the fourth sub-transistor T42, which is connected to a side of a channel portion CH2 of the fourth sub-transistor T42.

A gate electrode of the fifth transistor T5 and a gate electrode of the sixth transistor T6 may be provided as different portions, which overlap the semiconductor layer SEL, among the emission control lines ECL.

The semiconductor layer SEL may further include a channel portion of the fifth transistor T5, which overlaps the gate electrode of the fifth transistor T5, a source portion of the fifth transistor T5, which is connected to a side of the channel portion of the fifth transistor T5, a drain portion of the fifth transistor T5, which is connected to a side of a channel portion CH2 of the fifth transistor T5, a channel portion of the sixth transistor T6, which overlaps the gate electrode of the sixth transistor T6, a source portion of the sixth transistor T6, which is connected to a side of the channel portion of the sixth transistor T6, and a drain portion of the sixth transistor T6, which is connected to a side of a channel portion CH2 of the sixth transistor T6.

A gate electrode of the seventh transistor T7 may be provided as a portion, which overlaps the semiconductor layer SEL, among the bias control lines GBL.

The semiconductor layer SEL may further include a channel portion of the seventh transistor T7, which overlaps a gate electrode of the seventh transistor T7, a source portion of the seventh transistor T7, which is connected to a side of the channel portion of the seventh transistor T7, and a drain portion of the seventh transistor T7, which is connected to a side of a channel portion CH2 of the seventh transistor T7.

The anode initialization voltage line VAIL may be adjacent to the source portion of the seventh transistor T7.

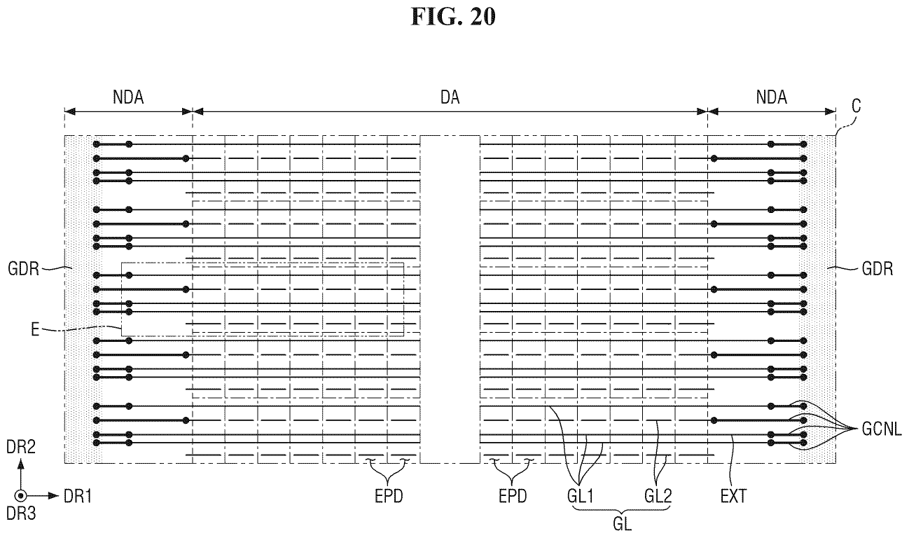

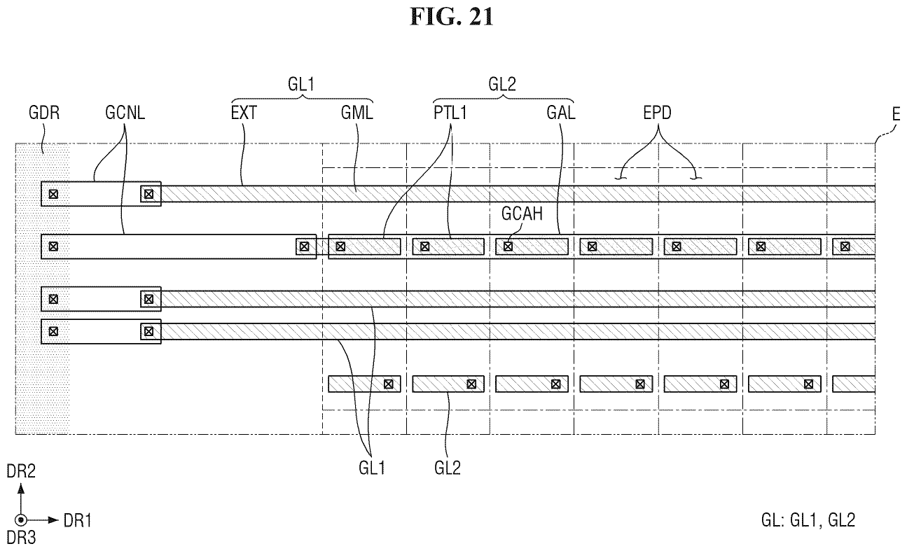

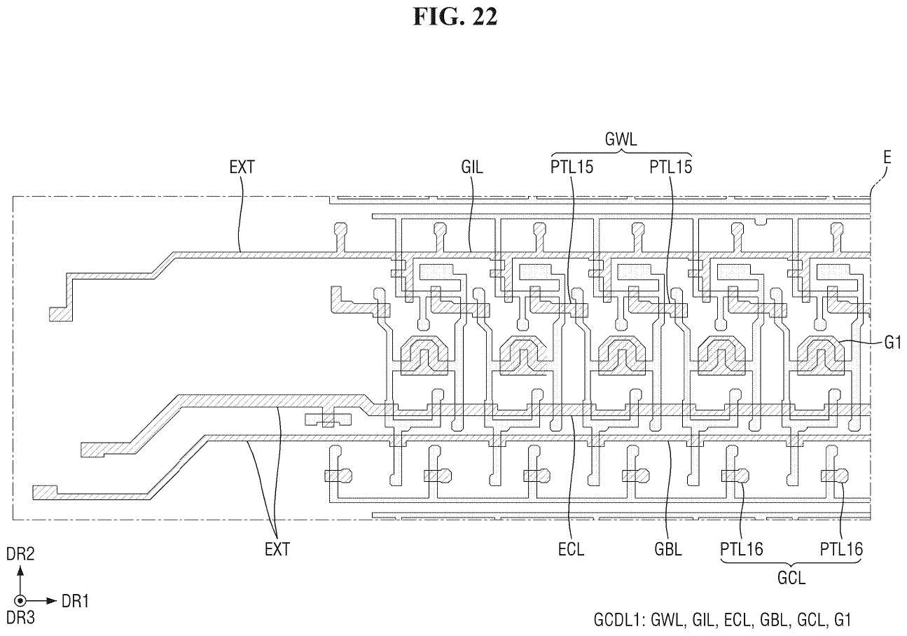

FIG. 20 is a schematic view illustrating gate lines of a portion C of FIG. 1 according to an embodiment. FIG. 21 is an enlarged schematic plan view illustrating a portion E of FIG. 20. FIG. 22 is a schematic plan view illustrating a semiconductor layer and a first gate conductive layer of a portion E of FIG. 20 according to an embodiment.

Referring to FIGS. 20 and 21, the display device 100 according to an embodiment may be substantially the same as the embodiments shown in FIGS. 13 to 19 except that each of multiple first split line portions PTL1 may overlap one emission pixel driver EPD. Therefore, the redundant description of FIGS. 13 to 19 will be omitted.

According to an embodiment shown in FIG. 22, the gate lines GL in the first direction DR1, which are disposed in the first gate conductive layer GDL, may include a scan write line GWL, a scan initialization line GIL, an emission control line ECL, a bias control line GBL and a gate control line GCL.

Each of the scan initialization line GIL, the emission control line ECL and the bias control line GBL of the gate lines GL may be disposed as the first gate line GL1 having a single line shape including the extension portion EXT.

Each of the scan write line GWL and the gate control line GCL of the gate lines GL may be disposed as the second gate line GL2 having a split shape.

For example, the first gate conductive layer GCDL may include a scan initialization line GIL, an emission control line ECL, a bias control line GBL, first split line portions PTL15 of the scan write line GWL, first split line portions PTL16 of the gate control line GCL, and a gate electrode G1 of the first transistor T1.

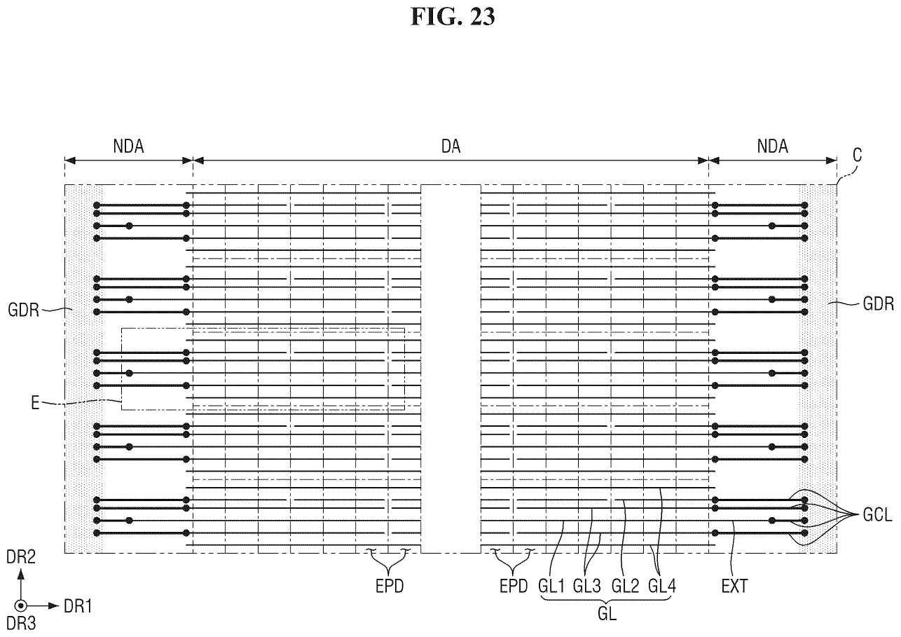

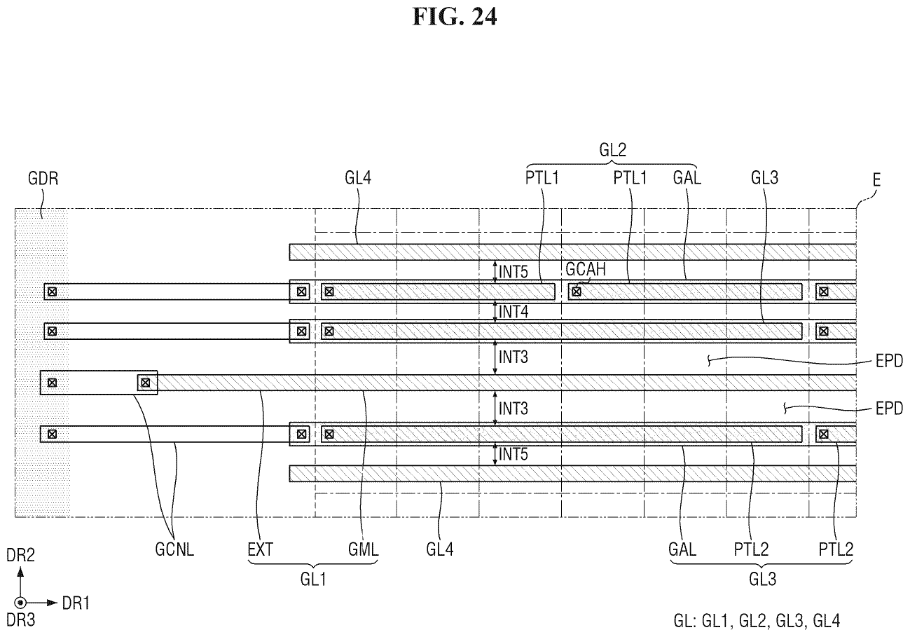

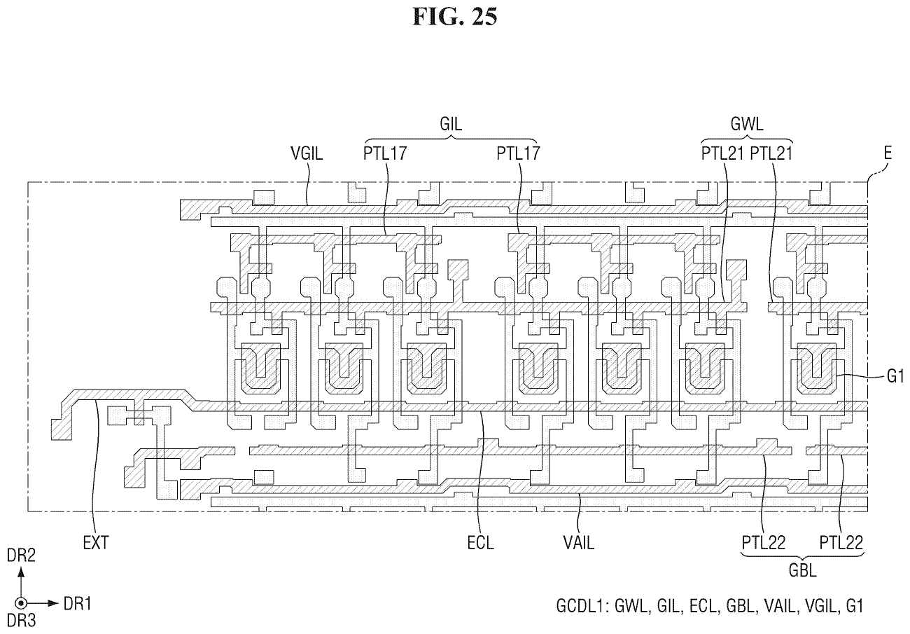

FIG. 23 is a schematic view illustrating gate lines of a portion C of FIG. 1 according to an embodiment. FIG. 24 is an enlarged schematic plan view illustrating a portion E of FIG. 23. FIG. 25 is a schematic plan view illustrating a semiconductor layer and a first gate conductive layer of a portion E of FIG. 23 according to an embodiment.

Referring to FIG. 23, the display device 100 according to an embodiment may be substantially the same as the embodiments shown in FIGS. 13 to 22 except that the gate lines GL may further include a third gate line GL3 together with the first gate lines GL1 and the second gate lines GL2. Therefore, the redundant description of FIGS. 13 to 22 will be omitted.

Like the second gate line GL2, the third gate line GL3 may be disposed in the display area DA in a shape divided into two or more portions, but may be split into portions smaller than those of the second gate line GL2.

Referring to FIG. 24, the third gate line GL3 may include multiple second split line portions PTL2 arranged in parallel with each other in the first direction DR1.

The second split line portions PTL2 may be disposed to have an extension length longer than the extension length of each of the first split line portions PTL1 of the second gate line GL2.

For example, each of the first split line portions PTL1 of the second gate line GL2 may overlap three emission pixel drivers EPD, and each of the second split line portions PTL2 of the third gate line GL3 may overlap six emission pixel drivers EPD.

However, FIGS. 23 and 24 are shown to be only an example, and in case that the condition that the first split line portion PTL1 is extended to be shorter than the second split line portion PTL2 is satisfied, the number of emission pixel drivers EPD, which overlap each of the first split line portion PTL1 and the second split line portion PTL2, is not limited to the examples shown in FIGS. 23 and 24.

The third gate line GL may further include a gate auxiliary line GAL electrically connected to the second split line portions PTL2.

In another embodiment, the third gate line GL may include gate auxiliary electrodes electrically connected to two of the second split line portions PTL2, which are adjacent to each other, instead of the gate auxiliary line GAL.

As shown in FIG. 24, in the second direction DR2, a minimum distance INT3 between the first gate line GL1 and the third gate line GL3, which are adjacent to each other, may be greater than a minimum distance INT4 between the second gate line GL2 and the third gate line GL3, which are adjacent to each other.

In case that the first gate lines GL1 adjacent to each other are disposed, the minimum distance INT3 between the first gate line GL1 and the third gate line GL3, which are adjacent to each other, may be greater than the minimum distance between the first gate lines GL1 adjacent to each other.

Otherwise, in case that the second gate lines GL2 adjacent to each other are disposed, the minimum distance INT3 between the first gate line GL1 and the third gate line GL3, which are adjacent to each other, may be greater than the minimum distance between the second gate lines GL2 adjacent to each other.

Otherwise, in case that the third gate lines GL3 adjacent to each other are disposed, the minimum distance INT3 between the first gate line GL1 and the third gate line GL3, which are adjacent to each other, may be greater than the minimum distance between the third gate lines GL3 adjacent to each other.

Also, in case that the first gate line GL1 is adjacent to each of the second gate line GL2 and the third gate line GL3, the minimum distance INT3 between the first gate line GL1 and the third gate line GL3, which are adjacent to each other, may be smaller than the minimum distance between the first gate line GL1 and the second gate line GL2, which are adjacent to each other.

A size of an electric field due to a difference in charges between the first gate line GL1 and the second gate line GL2, which are adjacent to each other, a size of an electric field due to a difference in charges between the first gate line GL1 and the third gate line GL3, which are adjacent to each other, and a size of an electric field due to a difference in charges between the second gate line GL2 and the third gate line GL3, which are adjacent to each other, may be reduced.

Therefore, damage to the semiconductor layer due to the charges accumulated in the line may be reduced.

According to an embodiment of FIG. 24, the gate lines GL may further include a fourth gate line GL4 that does not include the extension portion EXT while being disposed in the display area DA as a single line.

The fourth gate line GL4 may be a line that is disposed in the first gate conductive layer GCDL1 and does not overlap the semiconductor layer SEL.

Since the semiconductor layer is not damaged due to the charges accumulated in the fourth gate line GL4, the fourth gate line GL4 may not include the extension portion EXT.

In the second direction DR2, a minimum distance INT5 between the third gate line GL3 and the fourth gate line GL4, which are adjacent to each other, may be greater than the minimum distance INT4 between the second gate line GL2 and the third gate line GL3, which are adjacent to each other.

The size of the electric field may be reduced due to the difference in charges between the third gate line GL3 and the fourth gate line GL4, which are adjacent to each other.

Referring to FIG. 25, the gate lines GL in the first direction DR1, which are disposed in the first gate conductive layer GCDL, may include a scan write line GWL, a scan initialization line GIL, an emission control line ECL, a bias control line GBL, a gate initialization voltage line VGIL and an anode initialization voltage line VAIL.

The emission control line ECL of the gate lines GL may be disposed as the first gate line GL1 having a single line shape including the extension portion EXT.

The gate initialization voltage line VGIL and the anode initialization voltage line VAIL of the gate lines GL may be disposed as the fourth gate lines GL4 having a single line shape that does not include the extension portion EXT.

The scan initialization line GIL of the gate lines GL may be disposed as the second gate line GL2 including first split line portions PTL1 having a relatively small extension length.

Each of the scan write line GWL and the bias control line GBL of the gate lines GL may be disposed as the third gate line GL3 including second split line portions PTL2 of a relatively long extension length.

For example, the first gate conductive layer GCDL may include an emission control line ECL, a gate initialization voltage line VGIL, an anode initialization voltage line VAIL, first split line portions PTL17 of the scan initialization line GIL, second split line portions PTL21 of the scan write line GWL, second split line portions PTL22 of the bias control line GBL, and a gate electrode G1 of the first transistor T1.

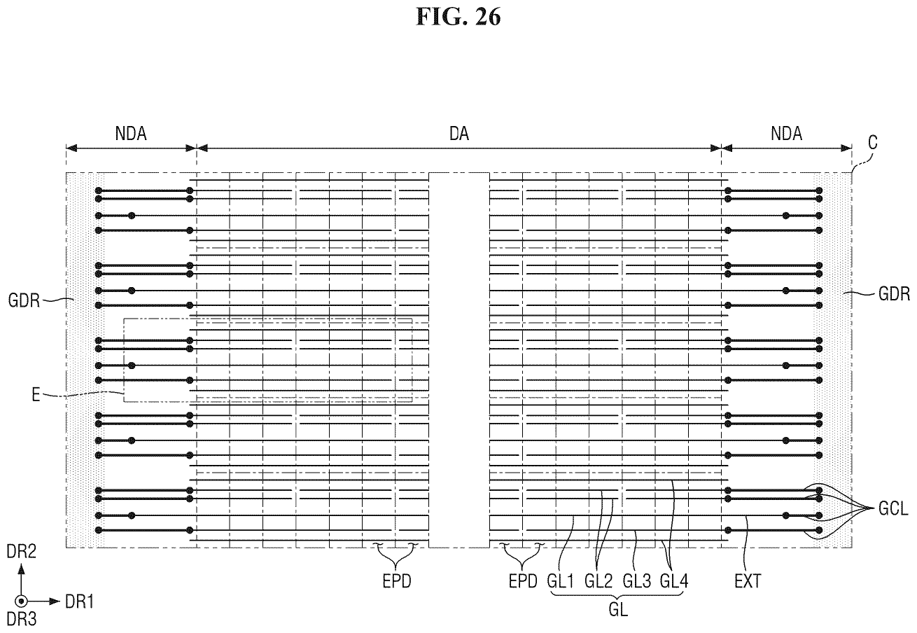

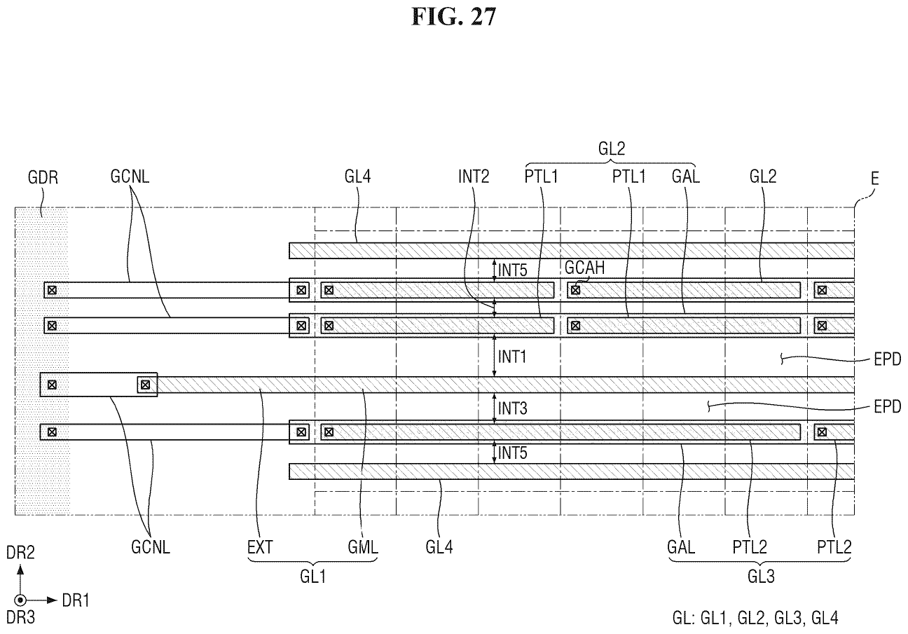

FIG. 26 is a schematic view illustrating gate lines of a portion C of FIG. 1 according to an embodiment. FIG. 27 is an enlarged schematic plan view illustrating a portion E of FIG. 26.

Referring to FIG. 26, the display device 100 according to an embodiment may be substantially the same as the embodiment shown in FIGS. 23, 24 and 25 except that the first gate line GL1 may be adjacent to the second gate line GL2 at a side of the second direction DR2 and may be adjacent to the third gate line GL3 at another side of the second direction DR2. Therefore, the redundant description of FIGS. 23, 24 and 25 will be omitted.

Referring to FIG. 27, the second gate line GL2 may include multiple first split line portions PTL1 arranged in parallel with each other in the first direction DR1.

The third gate line GL3 may include multiple second split line portions PTL2 arranged in parallel with each other in the first direction DR1.

The second split line portions PTL2 may be disposed to have an extension length longer than the extension length of each of the first split line portions PTL1 of the second gate line GL2.

According to an embodiment shown in FIGS. 26 and 27, considering that the extension length of the first split line portion PTL1 is shorter than that of the second split line portion PTL2, the minimum distance INT1 between the first gate line GL1 and the second gate line GL2, which are adjacent to each other, may be greater than the minimum distance INT3 between the first gate line GL1 and the third gate line GL3, which are adjacent to each other, in the second direction DR2.

Since a difference between the size of the electric field between the first gate line GL1 and the second gate line GL2, which are adjacent to each other, and the size of the electric field between the first gate line GL1 and the third gate line GL3, which are adjacent to each other, may be compensated by the distance difference, the difference between the electric fields may be reduced. Therefore, damage to the semiconductor layer due to the charges accumulated in the line may be reduced.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device, comprising:
a substrate including:
a display area including light emission areas; and
a non-display area disposed adjacent to the display area;
a circuit layer disposed on the substrate; and
an element layer disposed on the circuit layer, and including light emitting elements disposed in the light emission areas, wherein
the circuit layer includes:
emission pixel drivers electrically connected to the light emitting elements and disposed parallel with each other in a first direction and a second direction; and
gate lines electrically connected to the emission pixel drivers and extended in the first direction,
the gate lines are disposed in a first gate conductive layer on a first gate insulating layer overlapping a semiconductor layer disposed on the substrate,
the gate lines include first gate lines, each of which includes an extension portion extended to the non-display area and disposed in the non-display area, and
an extension length of the extension portion is equal to or greater than a width of the emission pixel driver in the first direction.

2. The display device of claim 1, wherein the extension length of the extension portion is twice or three times of the width of one of the emission pixel drivers in the first direction.

3. The display device of claim 1, wherein the extension portion includes a diagonal line oblique to the first direction and the second direction or at least one curve of which extension direction is variable.

4. The display device of claim 1, wherein an extension length of each of the first gate lines exceeds a width of the display area in the first direction.

5. The display device of claim 4, wherein
the gate lines further include second gate lines, each of which includes first split line portions disposed parallel with each other in the first direction, and
each of the first split line portions overlaps at least one emission pixel driver.

6. The display device of claim 5, wherein a minimum distance between the first gate line and one of the second gate lines, which are adjacent to each other, is greater than a minimum distance between second gate lines, which are adjacent to each other, in the second direction.

7. The display device of claim 6, wherein
at least one of the second gate lines further includes an auxiliary extension portion,
the auxiliary extension portion is extended from a first split line portion of the at least one of the second gate lines, which is adjacent to an edge of the display area, and is disposed in the non-display area, and
an extension length of the auxiliary extension portion exceeds the width of the emission pixel driver in the first direction.

8. The display device of claim 6, wherein
the gate lines further include a third gate line that includes second split line portions disposed at an extension length longer than that of each of the first split line portions and disposed parallel with each other in the first direction, and
each of the second split line portions overlaps two or more emission pixel drivers.

9. The display device of claim 8, wherein a minimum distance between the first gate line and the third gate line, which are adjacent to each other, is greater than a minimum distance between the second gate line and the third gate line, which are adjacent to each other, in the second direction.

10. The display device of claim 4, wherein the circuit layer includes:
a second gate insulating layer overlapping the first gate conductive layer;
a second gate conductive layer disposed on the second gate insulating layer;
an interlayer insulating layer overlapping the second gate conductive layer;
a first source drain conductive layer disposed on the interlayer insulating layer;
a first planarization layer overlapping the first source drain conductive layer;
a second source drain conductive layer disposed on the first planarization layer; and
a second planarization layer overlapping the second source drain conductive layer.

11. The display device of claim 4, wherein
one of the emission pixel drivers includes:
a first transistor electrically connected between a first node and a second node;
a pixel capacitor electrically connected between a first power line for transferring a first power source and a third node;
a second transistor electrically connected between a data line for transferring a data signal and the first node;
a third transistor electrically connected between the second node and the third node;
a fourth transistor electrically connected between the third node and a gate initialization voltage line for transferring a gate initialization voltage;
a fifth transistor electrically connected between the first power line and the first node;
a sixth transistor electrically connected between the second node and a fourth node; and
a seventh transistor electrically connected between an anode initialization voltage line for transferring an anode initialization voltage and the fourth node, the first node is electrically connected to a first electrode of the first transistor, the second node is electrically connected to a second electrode of the first transistor, the third node is electrically connected to a gate electrode of the first transistor, the fourth node is electrically connected to one of the light emitting elements,
the second transistor and the third transistor are turned on by a scan write signal transferred through a scan write line,
the fourth transistor is turned on by a scan initialization signal transferred through a scan initialization line,
the fifth transistor and the sixth transistor are turned on by an emission control signal transferred through an emission control line,
the seventh transistor is turned on by a bias control signal transferred through a bias control line, and
the gate lines include the scan write line, the scan initialization line, the emission control line and the bias control line.

12. A display device, comprising:
a substrate including:
a display area including light emission areas, and
a non-display area disposed adjacent to the display area;
a circuit layer disposed on the substrate; and
an element layer disposed on the circuit layer, and including light emitting elements disposed in the light emission areas, wherein
the circuit layer includes:
emission pixel drivers electrically connected to the light emitting elements and disposed parallel with each other in a first direction and a second direction;
gate lines electrically connected to the emission pixel drivers and extended in the first direction; and
a gate driving circuit disposed in a partial area of the non-display area between the display area and an edge of the substrate in the first direction, spaced apart from the display area and electrically connected to at least a portion of the gate lines,
the gate lines are disposed in a first gate conductive layer on a first gate insulating layer overlapping a semiconductor layer disposed on the substrate,
the gate lines include first gate lines, each of which includes an extension portion extended to the non-display area and disposed in the non-display area, and
an extension length of the extension portion is equal to or greater than a width of the emission pixel driver in the first direction.

13. The display device of claim 12, wherein the circuit layer further includes gate connection lines electrically connected between at least a portion of the gate lines and the gate driving circuit.

14. The display device of claim 12, wherein the extension portion includes a diagonal line oblique to the first direction and the second direction or at least one curve of which extension direction is variable.

15. The display device of claim 12, wherein an extension length of each of the first gate lines exceeds a width of the display area in the first direction.

16. The display device of claim 15, wherein
the gate lines further include second gate lines, each of which includes first split line portions disposed parallel with each other in the first direction,
each of the first split line portions overlaps at least one emission pixel driver, and
a minimum distance between the first gate line and the second gate line, which are adjacent to each other, is greater than a minimum distance between first gate lines, which are adjacent to each other, or a minimum distance between second gate lines, which are adjacent to each other, in the second direction.

17. The display device of claim 16, wherein
at least one of the second gate lines further includes an auxiliary extension portion,
the auxiliary extension portion is extended from a first split line portion of the at least one of the second gate lines, which is adjacent to an edge of the display area, and is disposed in the non-display area, and
an extension length of the auxiliary extension portion exceeds the width of the emission pixel driver in the first direction.

18. The display device of claim 16, wherein
the gate lines further include a third gate line that includes second split line portions disposed at an extension length longer than that of each of the first split line portions and disposed parallel with each other in the first direction,
each of the second split line portions overlaps two or more emission pixel drivers, and
a minimum distance between the first gate line and the third gate line, which are adjacent to each other, is greater than a minimum distance between the second gate line and the third gate line, which are adjacent to each other, in the second direction.

19. The display device of claim 15, wherein the circuit layer includes:
a second gate insulating layer overlapping the first gate conductive layer;
a second gate conductive layer disposed on the second gate insulating layer;
an interlayer insulating layer overlapping the second gate conductive layer;
a first source drain conductive layer disposed on the interlayer insulating layer;
a first planarization layer overlapping the first source drain conductive layer;
a second source drain conductive layer disposed on the first planarization layer; and
a second planarization layer overlapping the second source drain conductive layer.

20. The display device of claim 15, wherein
one of the emission pixel drivers includes:
a first transistor electrically connected between a first node and a second node;
a pixel capacitor electrically connected between a first power line for transferring a first power source and a third node;
a second transistor electrically connected between a data line for transferring a data signal and the first node;
a third transistor electrically connected between the second node and the third node;
a fourth transistor electrically connected between the third node and a gate initialization voltage line for transferring a gate initialization voltage;
a fifth transistor electrically connected between the first power line and the first node;
a sixth transistor electrically connected between the second node and a fourth node; and
a seventh transistor electrically connected between an anode initialization voltage line for transferring an anode initialization voltage and the fourth node, the first node is electrically connected to a first electrode of the first transistor, the second node is electrically connected to a second electrode of the first transistor, the third node is electrically connected to a gate electrode of the first transistor, the fourth node is electrically connected to one of the light emitting elements, the second transistor and the third transistor are turned on by a scan write signal transferred through a scan write line,
the fourth transistor is turned on by a scan initialization signal transferred through a scan initialization line,
the fifth transistor and the sixth transistor are turned on by an emission control signal transferred through an emission control line,
the seventh transistor is turned on by a bias control signal transmitted through a bias control line, and
the gate lines include the scan write line, the scan initialization line, the emission control line and the bias control line.
